(19) United States
(12) Patent Application Publication
(10) Pub. No.: US 2025/0216446 A1
(43) Pub. Date: Jul. 3, 2025

(54) BUILT-IN SELF-TEST CIRCUIT AND SYSTEM ON CHIP INCLUDING THE SAME

(71) Applicant: Samsung Electronics Co., Ltd., Suwon-si (KR)

(72) Inventors: Seki Kim, Suwon-si (KR); Hyunseok Nam, Suwon-si (KR); Takahiro Nomiyama, Suwon-si (KR)

(73) Assignee: Samsung Electronics Co., Ltd., Suwon-si (KR)

(21) Appl. No.: 18/967,880

(22) Filed: Dec. 4, 2024

(30) Foreign Application Priority Data
Dec. 29, 2023 (KR) 10-2023-0197529
Mar. 15, 2024 (KR) 10-2024-0036777

(51) Int. Cl. G01R 31/28; G01R 19/00; G01R 19/165

(52) U.S. Cl. CPC G01R 31/2884; G01R 19/0038; G01R 19/1659

(57) ABSTRACT

A system-on-chip (SoC) includes a monitoring circuit configured to determine whether a monitoring voltage has a value between a first reference voltage and a second reference voltage using a first supply voltage and a second supply voltage, and a built-in self-test (BIST) circuit configured to, in response to an enable signal, determine whether the monitoring circuit is operating normally. The BIST circuit may include a first test circuit configured to determine whether the first supply voltage has a value within a predetermined first supply range using the second supply voltage, a second test circuit configured to determine whether the first reference voltage has a value within a predetermined first reference range, and a third test circuit configured to determine whether the monitoring circuit compares a magnitude of the monitoring voltage with a magnitude of a first determination voltage having a value within a predetermined first comparison range from the first reference voltage.

### CROSS-REFERENCE TO RELATED APPLICATIONS

This present application claims priority to and the benefit under 35 USC §119(a)-(d) of Korean Patent Application Nos. 10-2023-0197529, filed on Dec. 29, 2023, and 10-2024-0036777, filed on Mar. 15, 2024, in the Korean Intellectual Property Office, the entire disclosures of which are incorporated herein by reference

### BACKGROUND

Semiconductor devices may include testing components.

### SUMMARY

Example embodiments provide a system-on-chip (SoC) including a built-in self-test (BIST) circuit that may improve the accuracy and reliability of monitoring a monitoring voltage that is output through a monitoring circuit.

According to an example embodiment, a system-on-chip (SoC) includes a monitoring circuit configured to determine whether a monitoring voltage has a value between a first reference voltage and a second reference voltage using a first supply voltage and a second supply voltage, and a built-in self-test (BIST) circuit configured to, in response to an enable signal, determine whether the monitoring circuit is operating normally. The BIST circuit may include a first test circuit configured to determine whether the first supply voltage has a value within a predetermined first supply range using the second supply voltage, a second test circuit configured to determine whether the first reference voltage has a value within a predetermined first reference range, and a third test circuit configured to determine whether the monitoring circuit compares a magnitude of the monitoring voltage with a magnitude of a first determination voltage having a value within a predetermined first comparison range from the first reference voltage.

According to an example embodiment, a system-on-chip (SoC) includes a monitoring circuit configured to determine whether a monitoring voltage has a value between a first reference voltage and second reference voltage, based on a first supply voltage and a second supply voltage, the monitoring circuit including a reference voltage generation circuit configured to generate the first reference voltage and the second reference voltage, a first comparator configured to compare magnitudes of the monitoring voltage and the first reference voltage, and a second comparator configured to compare magnitudes of the monitoring voltage and the second reference voltage, a first test circuit configured to determine whether the first supply voltage has a value within a predetermined first supply range, using the second supply voltage, a second test circuit configured to determine whether the first reference voltage has a value within a predetermined first reference range, and a third test circuit configured to determine whether the first comparator compares the magnitude of the monitoring voltage with a magnitude of a first determination voltage having a value within a predetermined first comparison range from the first reference voltage.

According to an example embodiment, there is provided a built-in self-test (BIST) circuit for determining whether a monitoring circuit is operating normally by determining whether a monitoring voltage has a value between a first reference voltage and a second reference voltage. The BIST circuit includes a first test circuit configured to determine whether a first supply voltage has a value within a predetermined first supply range, using a second supply voltage among a first supply voltage and the second supply voltage provided to the monitoring circuit, a second test circuit configured to determine whether the first reference voltage has a value within a predetermined first reference range, and a third test circuit configured to determine whether a first comparator compares a magnitude of the monitoring voltage with a magnitude of a first determination voltage having a value within a predetermined first comparison range from the first reference voltage.

### BRIEF DESCRIPTION OF DRAWINGS

FIG. 1A is a block diagram of a system-on-chip according to an example embodiment.

FIG. 1B is a block diagram illustrating a configuration of a monitoring circuit and a BIST circuit included in the system-on-chip according to an example embodiment.

FIG. 1C is a block diagram illustrating a configuration of the BIST circuit included in the system-on-chip according to an example embodiment.

FIG. 1D is a diagram illustrating a configuration in which a monitoring circuit outputs an error signal based on a monitoring voltage.

FIG. 2A is a circuit diagram of a 1-1 test circuit according to an example embodiment.

FIG. 2B is a circuit diagram of a 1-2 test circuit according to an example embodiment.

FIG. 3A is a diagram illustrating signals output by a first test circuit when a first supply voltage according to an example embodiment has a value within a first supply range.

FIG. 3B is a diagram illustrating signals output by a first test circuit when a first supply voltage according to an example embodiment has a value exceeding a first supply range.

FIG. 3C is a diagram illustrating signals output by a first test circuit when a first supply voltage according to an example embodiment has a value less than a first supply range.

FIG. 4A is a circuit diagram of a 1-1 test circuit according to an example embodiment.

FIG. 4B is a circuit diagram of a 1-2 test circuit according to an example embodiment.

FIG. 5A is a circuit diagram of a 1-1 test circuit according to an example embodiment.

FIG. 5B is a circuit diagram of a 1-2 test circuit according to an example embodiment.

FIG. 6A is a diagram illustrating signals output by a first test circuit when a first supply voltage according to an example embodiment has a value within a first supply range.

FIG. 6B is a diagram illustrating signals output by a first test circuit when a first supply voltage according to an example embodiment has a value exceeding a first supply range.

FIG. 6C is a diagram illustrating signals output by a first test circuit when a first supply voltage according to an example embodiment has a value less than a first supply range.

FIG. 7 is a diagram illustrating a configuration in which a second test circuit monitors a first reference voltage and a second reference voltage according to an example embodiment.

FIG. 8A is a circuit diagram illustrating a configuration of a 2-1 test circuit according to an example embodiment.

FIG. 8B is a diagram illustrating signals output by the 2-1 test circuit of FIG. 8A when the first reference voltage has a value between a first upper voltage and a first lower voltage.

FIG. 8C is a diagram illustrating signals output by the 2-1 test circuit of FIG. 8A when the first reference voltage has a value greater than or equal to the first upper voltage.

FIG. 8D is a diagram illustrating signals output by the 2-1 test circuit of FIG. 8A when the first reference voltage has a value less than or equal to the first lower voltage.

FIG. 9A is a circuit diagram illustrating a configuration of a 2-2 test circuit according to an example embodiment.

FIG. 9B is a diagram illustrating signals output by the 2-2 test circuit of FIG. 9A when the second reference voltage has a value between a second upper voltage and a second lower voltage.

FIG. 9C is a diagram illustrating signals output by the 2-2 test circuit of FIG. 9A when the second reference voltage has a value greater than or equal to the second upper voltage.

FIG. 9D is a diagram illustrating signals output by the 2-2 test circuit of FIG. 9A when the second reference voltage has a value less than or equal to the second lower voltage.

FIG. 10A is a circuit diagram illustrating a configuration of a 2-1 test circuit according to an example embodiment.

FIG. 10B is a diagram illustrating signals output by the 2-1 test circuit of FIG. 10A when a first reference voltage has a value between a first upper voltage and a first lower voltage.

FIG. 10C is diagram illustrating signals output by the 2-1 test circuit of FIG. 10A when the first reference voltage has a value greater than or equal to the first upper voltage.

FIG. 10D is a diagram illustrating signals output by the 2-1 test circuit of FIG. 10A when the first reference voltage has a value less than or equal to the first lower voltage.

FIG. 11A is a circuit diagram illustrating a configuration of a 2-2 test circuit according to an example embodiment.

FIG. 11B is a diagram illustrating signals output by the 2-2 test circuit of FIG. 11A when a second reference voltage has a value between a second upper voltage and a second lower voltage.

FIG. 11C is a diagram illustrating signals output by the 2-2 test circuit of FIG. 11A when a second reference voltage has a value greater than or equal to the second upper voltage.

FIG. 11D is a diagram illustrating signals output by the 2-2 test circuit of FIG. 11A when the second reference voltage has a value less than or equal to the second lower voltage.

FIG. 12A is a circuit diagram illustrating a configuration of a 3-1 test circuit according to an example embodiment.

FIG. 12B is a diagram illustrating a configuration in which the 3-1 test circuit of FIG. 12A outputs a first comparison test signal.

FIG. 13A is a circuit diagram illustrating a configuration of a 3-2 test circuit according to an example embodiment.

FIG. 13B is a diagram illustrating a configuration in which the 3-2 test circuit of FIG. 13A outputs a second comparison test signal.

### DETAILED DESCRIPTION

Hereinafter, example embodiments will be described with reference to the accompanying drawings.

The terms, such as “first,” “second,” or the like, may represent various elements regardless of order and/or importance. Such terms may only be used to distinguish one element from another element, and do not limit the order and/or importance of the elements.

Example embodiments relate to a built-in self-test (BIST) circuit and a system-on-chip (SoC) including the same.

With the advancement of semiconductor manufacturing technology, the integration level of semiconductor devices is increasing, while the likelihood of failure of semiconductor devices is also growing. Therefore, a process of detecting and analyzing failures occurring in semiconductor devices is becoming increasingly important.

For example, semiconductor devices have been tested using external specific-purpose apparatuses. However, the emergence of system-on-chip (SoC) technology, which implements an entire system on a single chip, has led to significant changes in methods of testing semiconductor devices.

A system-on-chip uses a plurality of built-in memory devices having large data input/output (I/O) bandwidths to enhance performance. Testing such built-in memory devices using an external specific-purpose apparatus according to conventional approaches is significantly inefficient due to a lack of the number of channels in a test apparatus, a limitation of a high-speed test, and low accessibility to the built-in memory devices.

To address the above issues, a method of incorporating a built-in self-test (BIST) circuit in a system-on-chip is provided. Such a method offers advantages over test methods according to conventional approaches in terms of high-speed test. Such a method may be employed as a method of testing components of a system-on-chip.

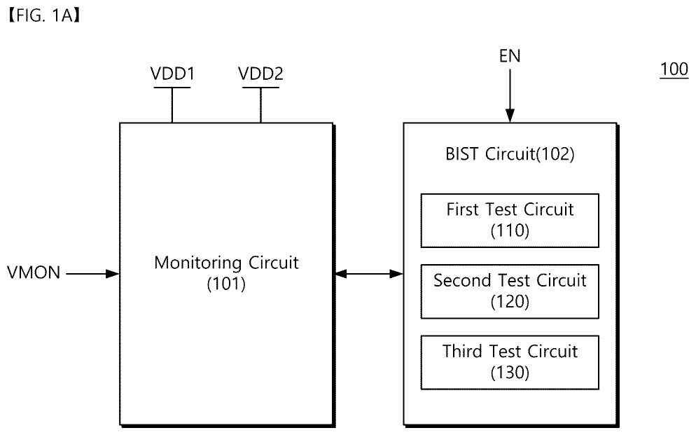

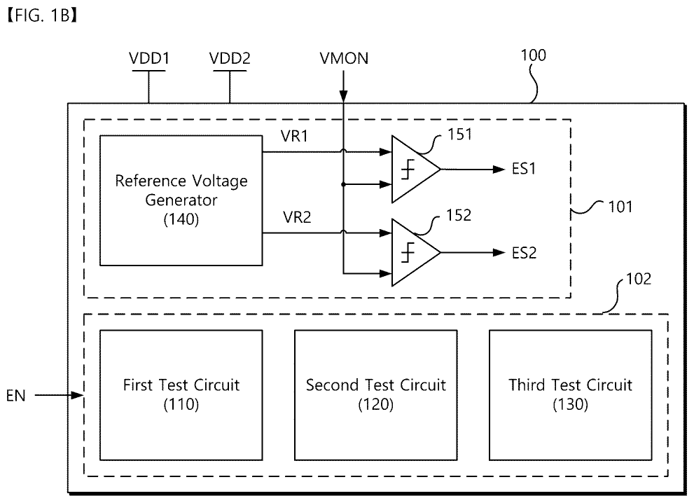

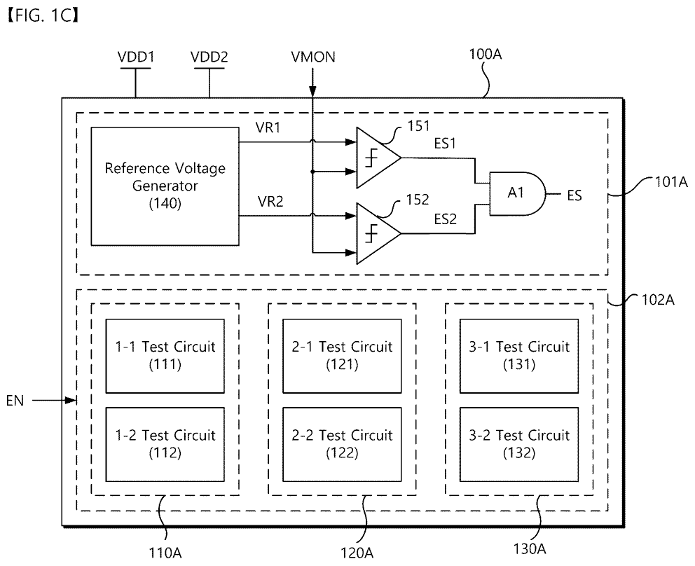

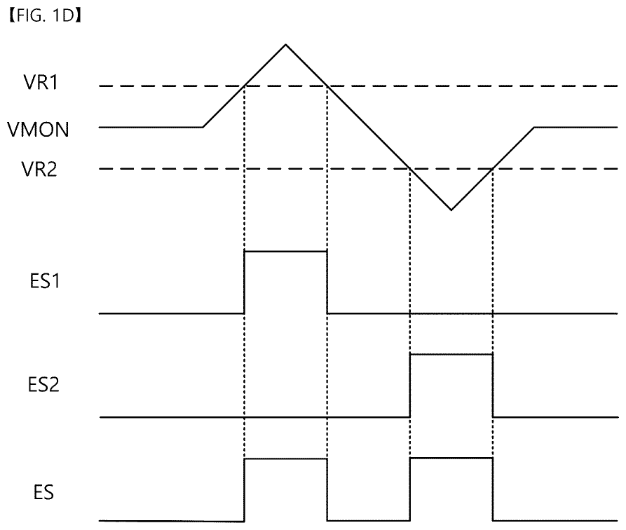

FIG. 1A is a block diagram of a system-on-chip according to an example embodiment. FIG. 1B is a block diagram illustrating a configuration of a monitoring circuit and a BIST circuit included in the system-on-chip according to an example embodiment. FIG. 1C is a block diagram illustrating a configuration of the BIST circuit included in the system-on-chip according to an example embodiment. FIG. 1D is a diagram illustrating a configuration in which a monitoring circuit outputs an error signal based on a monitoring voltage.

Referring to FIGS. 1A to 1D, a system-on-chip (SoC) 100 or 100A according to an example embodiment may include a monitoring circuit 101 or 101A and a built-in self-test (BIST) circuit 102 or 102A.

For example, the SoC 100 or 100A may be understood as being provided in an automotive electrical system.

A malfunction in an automotive electrical system may pose a safety risk to a driver and passengers. Accordingly, the ISO 26262 standard defines an automotive safety integrity level (ASIL) for various hardware devices or IP blocks used in the automotive electronic system.

The ASIL may be classified into ASIL A, ASIL B, ASIL C, and ASIL D depending on importance in terms of stability. For example, a semiconductor chip corresponding to a function directly related to human safety, such as an airbag or engine management, requires ASIL D, while components that are not directly related to safety, such as lighting, require ASIL B or ASIL A.

A monitoring circuit 101 or 101A is required to obtain ASIL certification for a semiconductor integrated circuit (for example, the SoC 100 or 100A) provided in the automotive electrical system. The monitoring circuit 101 or 101A serves as a diagnostic circuit to diagnose whether power is appropriately supplied to the semiconductor integrated circuit.

The monitoring circuit 101 or 101A may define a normal range of power used in the semiconductor integrated circuit, and operate in a manner of outputting an error signal when the power falls outside the normal range.

However, characteristics of the monitoring circuit 101 or 101A may change over time or temperature, potentially leading to inaccuracy in determining whether a power supply operates normally.

Accordingly, to achieve higher ASIL certification, a BIST 102 or 102A becomes increasingly important to check whether the monitoring circuit 101 or 101A is operating normally.

For example, the SoC 100 or 100A may include a monitoring circuit 101 or 101A to monitor (or determine) whether the magnitude of a monitoring voltage VMON is within the normal range.

The monitoring circuit 101 or 101A may monitor whether the monitoring voltage VMON has a value within the normal range, using a first supply voltage VDD1 and a second supply voltage VDD2.

The normal range may be understood as a range of the magnitude of the monitoring voltage VMON that allows the device or system (for example, an automotive electrical system) provided with the SoC 100 or 100A to operate normally using the monitoring voltage VMON.

Referring to FIG. 1B, the monitoring circuit 101 may include a reference voltage generation circuit 140, a first comparator 151, and a second comparator 152.

For example, the monitoring circuit 101 may include a reference voltage generation circuit 140 generating reference voltages VR1 and VR2 serving as criteria for determining whether the monitoring voltage VMON is within the normal range.

The reference voltage generation circuit 140 may generate a first reference voltage VR1 and a second reference voltage VR2.

For example, the reference voltage generation circuit 140 may generate a first reference voltage VR1 serving as an upper criterion within the normal range of the monitoring voltage VMON.

Also, the reference voltage generation circuit 140 may generate a second reference voltage VR2 serving as a lower criterion within the normal range of the monitoring voltage VMON.

The monitoring circuit 101 may include a first comparator 151 and a second comparator 152 comparing the monitoring voltage VMON with a voltage output from the reference voltage generation circuit 140.

For example, the monitoring circuit 101 may include a first comparator 151 comparing a magnitude of the monitoring voltage VMON with a magnitude of the first reference voltage VR1.

The first comparator 151 may determine whether the magnitude of the monitoring voltage VMON having a high level is greater than or equal to the magnitude of the first reference voltage VR1.

For example, the first comparator 151 may output a first error signal ES1 having a high level in response to the magnitude of the monitoring voltage VMON being greater than or equal to the magnitude of the first reference voltage VR1.

Also, the monitoring circuit 101 may include a second comparator 152 comparing the magnitude of the monitoring voltage VMON with the magnitude of the second reference voltage VR2.

For example, the second comparator 152 may determine whether the magnitude of the monitoring voltage VMON is less than or equal to the magnitude of the second reference voltage VR2.

For example, the second comparator 152 may output a second error signal ES2 having a high level in response to the magnitude of the monitoring voltage VMON being less than or equal to the magnitude of the second reference voltage VR2.

Referring to FIG. 1C, the monitoring circuit 101A may further include a first AND gate A1 connected to the first comparator 151 and the second comparator 152.

The system-on-chip 100A and each of the components of the system-on-chip 100A illustrated in FIG. 1C may be understood as an example of the system-on-chip 100 and each of the components of the system-on-chip 100 illustrated in FIG. 1A. Therefore, the same or substantially the same components are represented by the same reference numerals, and redundant descriptions are omitted to avoid repetition.

The first AND gate A1 may perform a logical AND operation on the first error signal ES1 and the second error signal ES2.

For example, the first AND gate A1 may perform a logical AND operation on the first error signal ES1 and the second error signal ES2 to output an error signal ES.

The error signal ES may be understood as a signal indicating whether the monitoring voltage VMON has a value between the first reference voltage VR1 and the second reference voltage VR2.

For example, referring to FIG. 1D, the error signal ES may be output to have a high level while the monitoring voltage VMON has a value greater than or equal to the first reference voltage VR1 or a value less than or equal to the second reference voltage VR2.

For example, the monitoring circuit 101 or 101A may determine whether the monitoring voltage VMON has a value between the first reference voltage VR1 and the second reference voltage VR2. For example, the monitoring circuit 101 or 101A may output an error signal ES based on whether the monitoring voltage VMON has a value between the first reference voltage VR1 and the second reference voltage VR2.

Also, referring to FIG. 1A, the system on chip 100 may include a BIST circuit 102 determining whether the monitoring circuit 101 is operating normally.

For example, the system on chip 100 may include a BIST circuit 102 determining whether each component of the monitoring circuit 101 is operating normally, in response to an enable signal EN.

Also, the BIST circuit 102 may determine whether a first supply voltage VDD1 and a second supply voltage VDD2, input to the monitoring circuit 101, each have a value within the normal range.

Referring to FIG. 1B, the BIST circuit 102 may include a first test circuit 110, a second test circuit 120, and a third test circuit 130.

For example, the BIST circuit 102 may include a first test circuit 110 determining whether each of the first and second supply voltages VDD1 and VDD2 has a value within a predetermined range.

The first test circuit 110 may determine whether each of the first and second supply voltages VDD1 and VDD2 has a value within the predetermined range and is supplied to the monitoring circuit 101.

Referring to FIG. 1C, the first test circuit 110A according to an example embodiment may include a 1-1 test circuit 111 and a 1-2 test circuit 112. The operations described below as being performed by the 1-1 test circuit 111 and/or the 1-2 test circuit 112 may also be understood as being performed by the first test circuit 110A.

The 1-1 test circuit 111 may determine whether the first supply voltage VDD1 has a value within a predetermined first supply range. Also, the 1-2 test circuit 112 may determine whether the second supply voltage VDD2 has a value within a predetermined second supply range.

The first supply range may be understood as a predetermined range for the magnitude of the first supply voltage VDD1 that allows the monitoring circuit 101 or 101A to operate normally as the first supply voltage VDD1 is supplied.

The second supply range may be understood as a predetermined range for the magnitude of the second supply voltage VDD2 that allows the monitoring circuit 101 or 101A to operate normally as the second supply voltage VDD2 is supplied.

For example, the 1-1 test circuit 111 may determine whether the first supply voltage VDD1 has a value within the predetermined first supply range, using the second supply voltage VDD2.

The 1-2 test circuit 112 may determine whether the second supply voltage VDD2 has a value within the predetermined second supply range, using the first supply voltage VDD1.

Referring to the above-described configurations, the first test circuit 110 may determine whether one of the supply voltages VDD1 and VDD2 has a value within the predetermined range, using the other supply voltage.

As a result, the system on chip 100 or 100A according to an example embodiment may improve the accuracy and reliability of test result for each of the supply voltages VDD1 and VDD2.

Also, the BIST circuit 102 or 102A may include a second test circuit 120 determining whether each of the first reference voltage VR1 and the second reference voltage VR2 has a value within a predetermined range.

For example, the second test circuit 120 may determine whether the first reference voltage VR1 has a value within a first reference range. Also, the second test circuit 120 may determine whether the second reference voltage VR2 has a value within a second reference range.

The first reference range may be understood as a predetermined range for the magnitude of the first reference voltage VR1, and the second reference range may be understood as a predetermined range for the magnitude of the second reference voltage VR2.

Continuing to refer to FIG. 1C, the second test circuit 120A may include a 2-1 test circuit 121 and a 2-2 test circuit 122. The operations described below as being performed by the 2-1 test circuit 121 and/or the 2-2 test circuit 122 may also be understood as being performed by the second test circuit 120A.

The 2-1 test circuit 121 may determine whether the first reference voltage VR1 has a value within the first reference range, and the 2-2 test circuit 122 may determine whether the second reference voltage VR2 has a value within the second reference range.

For example, the second test circuit 120A may determine whether the reference voltage generation circuit 140 outputs the first reference voltage VR1 and the second reference voltage VR2 to have values within predetermined ranges, respectively.

Also, the BIST circuit 102 or 102A may include a third test circuit 130 determining whether each of the first comparator 151 and the second comparator 152 compares the monitoring voltage VMON with a value within a predetermined range from the first reference voltage VR1 and the second reference voltage VR2.

For example, the third test circuit 130 may determine whether the first comparator 151 compares the monitoring voltage VMON with a first determination voltage having a value within a predetermined first comparison range from the first reference voltage VR1.

Also, the third test circuit 130 may determine whether the second comparator 152 compares the monitoring voltage VMON to a second determination voltage having a value within a predetermined second comparison range from the second reference voltage VR2.

For example, the first comparison range may be referred to as an offset (or error) of the first comparator 151, and the second comparison range may be referred to as an offset (or error) of the second comparator 152.

For example, when the first comparator 151 compares the monitoring voltage VMON with a value within the first comparison range from the first reference voltage VR1, the system-on-chip 100 or 100A may determine that the first comparator 151 is operating normally.

When the second comparator 152 compares the monitoring voltage VMON with a value within the second comparison range from the second reference voltage VR2, the system-on-chip 100 or 100A may determine that the second comparator 152 is operating normally.

Referring to FIG. 1C, the third test circuit 130A according to an example embodiment may include a 3-1 test circuit 131 and a 3-2 test circuit 132. The operations described below as being performed by the 3-1 test circuit 131 and/or the 3-2 test circuit 132 may also be understood as being performed by the third test circuit 130A.

The 3-1 test circuit 131 may determine whether the first comparator 151 compares the monitoring voltage VMON with a first determination voltage having a value within the first comparison range from the first reference voltage VR1.

For example, the 3-1 test circuit 131 may input a voltage, which increases by a unit voltage based on a predetermined period, to the first comparator 151.

The 3-1 test circuit 131 may determine whether a voltage at a time point, at which the first comparator 151 determines that the input voltage has the same value as the monitoring voltage VMON, has a value within the first comparison range from the first reference voltage VR1.

The 3-2 test circuit 132 may determine whether the second comparator 152 compares the monitoring voltage VMON with a second determination voltage having a value within the second comparison range from the second reference voltage VR2.

For example, the 3-2 test circuit 132 may input a voltage, which increases by a unit voltage based on a predetermined period, to the second comparator 152.

The 3-2 test circuit 132 may determine whether a voltage, at a time point at which the second comparator 152 determines that the input voltage has the same value as the monitoring voltage VMON, has a value within the second comparison range from the second reference voltage VR2.

For example, the third test circuit 130A may determine whether each of the first comparator 151 and the second comparator 152 is operating normally.

Referring to the above-described configurations, the BIST circuit 102 or 102A may determine whether each of the supply voltages VDD1 and VDD2, input to the monitoring circuit 101 or 101A, has a value within a predetermined supply range. In addition, the BIST circuit 102 or 102A may determine whether each component of the monitoring circuit 101 or 101A is operating normally.

As a result, the system-on-chip 100 or 100A according to an example embodiment may accurately determine whether the monitoring circuit 101 or 101A is operating normally.

Further, the system-on-chip 100 or 100A according to an example embodiment may improve the accuracy and reliability of the monitoring results for the monitoring voltage VMON output from the monitoring circuit 101 or 101A.

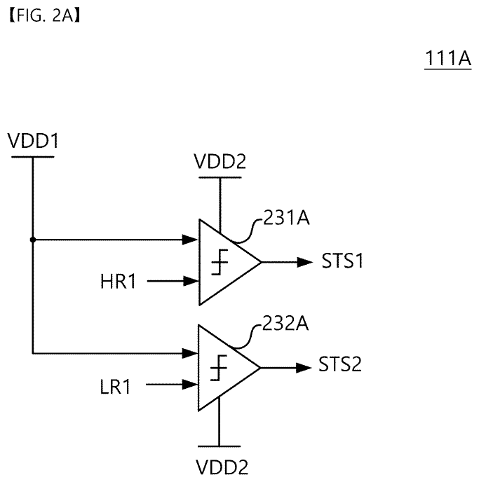

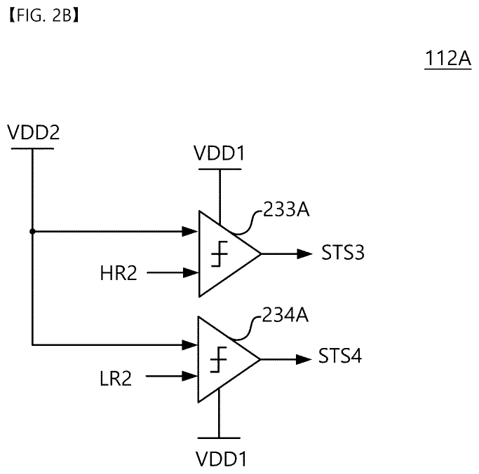

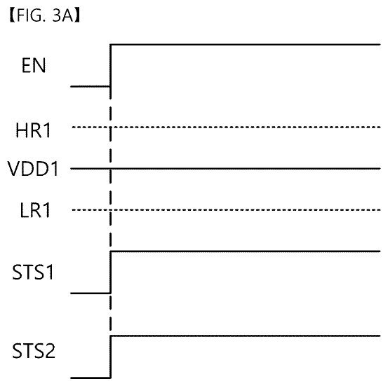

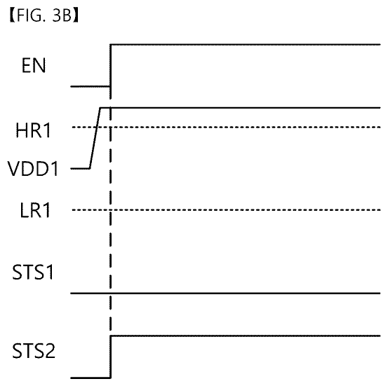

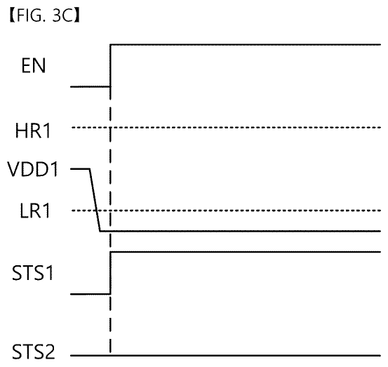

FIG. 2A is a circuit diagram of a 1-1 test circuit according to an example embodiment. FIG. 2B is a circuit diagram of a 1-2 test circuit according to an example embodiment. FIG. 3A is a diagram illustrating signals output by a first test circuit when a first supply voltage according to an example embodiment has a value within a first supply range. FIG. 3B is a diagram illustrating signals output by a first test circuit when a first supply voltage according to an example embodiment has a value exceeding a first supply range. FIG. 3C is a diagram illustrating signals output by a first test circuit when a first supply voltage according to an example embodiment has a value less than a first supply range.

Referring to FIG. 2A, a 1-1 test circuit 111A according to an example embodiment may include a first supply comparator 231A and a second supply comparator 232A. The 1-1 test circuit 111A illustrated in FIG. 2A may be understood as an example of the 1-1 test circuit 111 illustrated in FIG. 1C.

For example, the 1-1 test circuit 111A may include a first supply comparator 231A comparing the first supply voltage VDD1 and the first upper reference voltage HR1.

According to an example embodiment, the first supply comparator 231A may compare a magnitude of the first supply voltage VDD1 and a magnitude of the first upper reference voltage HR1 to output a first supply test signal STS1.

For example, referring to FIG. 3B, the first supply comparator 231A may output a first supply test signal STS1 having a low level while the first supply voltage VDD1 has a value greater than or equal to the first upper reference voltage HR1.

For example, referring to FIG. 3A, the first supply comparator 231A may output a first supply test signal STS1 having a high level while the first supply voltage VDD1 has a value less than the first upper reference voltage HR1.

The 1-1 test circuit 111A may include a second supply comparator 232A comparing the first supply voltage VDD1 and the first lower reference voltage LR1.

According to an example embodiment, the second supply comparator 232A may compare a magnitude of the first supply voltage VDD1 and a magnitude of the first lower reference voltage LR1 to output a second supply test signal STS2.

For example, referring to FIG. 3C, the second supply comparator 232A may output a second supply test signal STS2 having a low level while the first supply voltage VDD1 has a value less than or equal to the first lower reference voltage LR1.

For example, referring to FIG. 3A, the second supply comparator 232A may output a second supply test signal STS2 having a high level while the first supply voltage VDD1 has a value greater than the first lower reference voltage LR1.

For example, the 1-1 test circuit 111A may determine whether the first supply voltage VDD1 has a value between the first upper reference voltage HR1 and the first lower reference voltage LR1.

For example, the first upper reference voltage HR1 and the first lower reference voltage LR1 may be understood as voltages generated by the reference voltage generation circuit 140 of FIG. 1A.

Also, according to one embodiment, the first upper reference voltage HR1 and the first lower reference voltage LR1 may have a value within a specified range from a predetermined target value of the first supply voltage VDD1. The target value of the first supply voltage VDD1 may be a magnitude value of the first supply voltage VDD1 set for an ideal operation of the monitoring circuit 101 or 101A, and may be understood as a value previously stored in the system-on-chip 100 or 100A.

For example, the first upper reference voltage HR1 may have a value equal to 1.1 times the target value of the first supply voltage VDD1. For example, the first lower reference voltage LR1 may have a value equal to 0.9 times the target value of the first supply voltage VDD1.

For example, the 1-1 test circuit 111A may determine whether the first supply voltage VDD1 has a value having an error of less than 10% from the target value of the first supply voltage VDD1.

However, the values of the first upper reference voltage HR1 and the first lower reference voltage LR1 are not limited to the above-described examples.

According to an example embodiment, each of the first and second supply comparators 231A and 232A may operate using the second supply voltage VDD2.

For example, the first supply comparator 231A may compare the magnitudes of the first supply voltage VDD1 and the first upper reference voltage HR1 using the second supply voltage VDD2. The second supply comparator 232A may compare the magnitudes of the first supply voltage VDD1 and the first lower reference voltage LR1 using the second supply voltage VDD2.

For example, the 1-1 test circuit 111A may determine whether the first supply voltage VDD1 has a value between the first upper reference voltage HR1 and the first lower reference voltage LR1, using the second supply voltage VDD2

A voltage range from the first upper reference voltage HR1 to the first lower reference voltage LR1 may be understood as a first supply range predetermined for the first supply voltage VDD1.

Referring to FIG. 2B, a 1-2 test circuit 112A according to an example embodiment may include a third supply comparator 233A and a fourth supply comparator 234A. The 1-2 test circuit 112A illustrated in FIG. 2B may be understood as an example of the 1-2 test circuit 112 illustrated in FIG. 1C.

For example, the 1-2 test circuit 112A may include a third supply comparator 233A comparing the second supply voltage VDD2 and the second upper reference voltage HR2.

According to an example embodiment, the third supply comparator 233A may compare the magnitudes of the second supply voltage VDD2 and the second upper reference voltage HR2 to output a third supply test signal STS3.

For example, the third supply comparator 233A may output a third supply test signal STS3 having a low level while the second supply voltage VDD2 has a value greater than or equal to the second upper reference voltage HR2.

For example, the third supply comparator 233A may output a third supply test signal STS3 having a high level while the second supply voltage VDD2 has a value less than the second upper reference voltage HR2.

The 1-2 test circuit 112A may include a fourth supply comparator 234A comparing the second supply voltage VDD2 and the second lower reference voltage LR2.

According to an example embodiment, the fourth supply comparator 234A may compare the magnitudes of the second supply voltage VDD2 and the second lower reference voltage LR2 to output a fourth supply test signal STS4.

For example, the fourth supply comparator 234A may output a fourth supply test signal STS4 having a low level while the second supply voltage VDD2 has a value less than or equal to the second lower reference voltage LR2.

For example, the fourth supply comparator 234A may output a fourth supply test signal STS4 having a high level while the second supply voltage VDD2 has a value greater than the second lower reference voltage LR2.

For example, the 1-2 test circuit 112A may determine whether the second supply voltage VDD2 has a value between the second upper reference voltage HR2 and the second lower reference voltage LR2.

The second upper reference voltage HR2 and the second lower reference voltage LR2 may be understood as voltages generated by the reference voltage generation circuit 140 of FIG. 1A.

According to one embodiment, the second upper reference voltage HR2 and the second lower reference voltage LR2 may have a value within a specified range from a predetermined target value of the second supply voltage VDD2. The target value of the second supply voltage VDD2 may be understood as a magnitude value of the second supply voltage VDD2, which is ideal for driving the monitoring circuit 101 or 101A.

For example, the second upper reference voltage HR2 may have a value equal to 1.1 times the target value of the second supply voltage VDD2. For example, the second lower reference voltage LR2 may have a value equal to 0.9 times the target value of the second supply voltage VDD2.

For example, the 1-2 test circuit 112A may determine whether the second supply voltage VDD2 has a value within 10% of the target value of the second supply voltage VDD2.

However, the values of the second upper reference voltage HR2 and the second lower reference voltage LR2 are not limited to the above-described examples.

For example, the second upper reference voltage HR2 may be referenced as having the same value as the first upper reference voltage HR1 and the second lower reference voltage LR2 may be referenced as having the same value as the first lower reference voltage LR1, but example embodiments are not limited thereto.

According to an example embodiment, each of the third and fourth supply comparators 233A and 234A may operate using the first supply voltage VDD1.

For example, the third supply comparator 233A may compare the magnitudes of the second supply voltage VDD2 and the second upper reference voltage HR2 using the first supply voltage VDD1. The fourth supply comparator 234A may compare the magnitudes of the second supply voltage VDD2 and the second lower reference voltage LR2 using the first supply voltage VDD1.

For example, the 1-2 test circuit 112A may determine whether the second supply voltage VDD2 has a value between the second upper reference voltage HR2 and the second lower reference voltage LR2, using the first supply voltage VDD1.

A voltage range from the second upper reference voltage HR2 to the second lower reference voltage LR2 may be understood as a second supply range predetermined for the second supply voltage VDD2.

According to an example embodiment, the 1-1 test circuit 111A of FIG. 2A and the 1-2 test circuit 112A of FIG. 2B may be understood as being included in the first test circuit 110A of FIG. 1B. Therefore, the operation of each of the 1-1 test circuit 111A and the 1-2 test circuit 112A may be understood as being performed by the first test circuit 110A of FIG. 1B.

Referring to the above-described configurations, the 1-1 test circuit 111A and the 1-2 test circuit 112A according to an example embodiment may determine whether each of the supply voltages VDD1 and VDD2 supplied to the monitoring circuit 101 or 101A has a value within a predetermined supply range.

As a result, the system-on-chip 100 or 100A according to an example embodiment may determine whether each of the supply voltages VDD1 and VDD2 supplied to the monitoring circuit 101 or 101A has a value within the normal range.

Each of the 1-1 test circuit 111A and the 1-2 test circuit 112A may determine whether one of the different supply voltages VDD1 and VDD2 has a value within the predetermined supply range, using the other supply voltage.

For example, the first test circuit 110A may determine whether each of the first supply voltage VDD1 and the second supply voltage VDD2 has a value within the predetermined supply range, based on cross-checking.

As a result, the system-on-chip 100 or 100A according to an example embodiment may improve the accuracy and reliability in determining whether each of the supply voltages VDD1 and VDD2 has a value within the predetermined supply range through the first test circuit 110A.

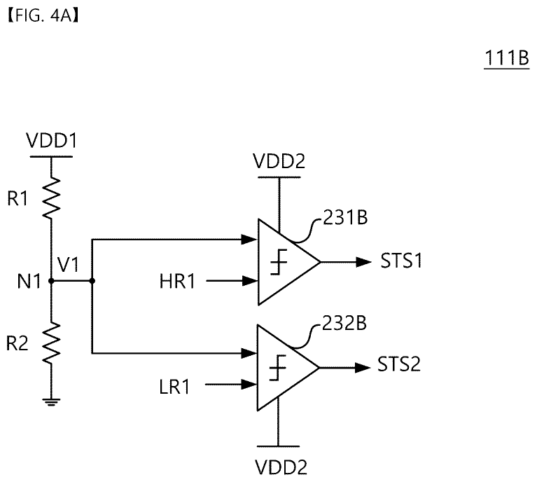

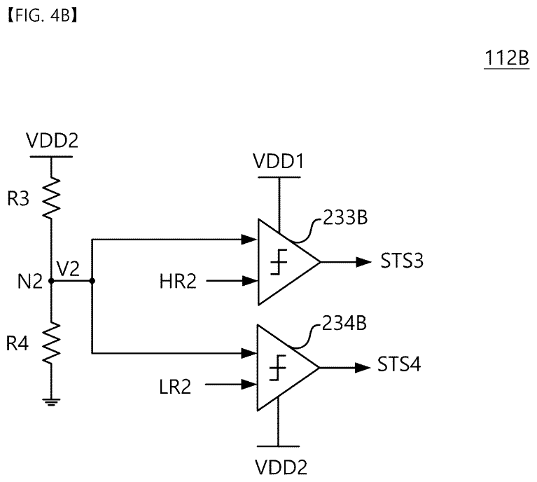

FIG. 4A is a circuit diagram of a 1-1 test circuit according to an example embodiment, and FIG. 4B is a circuit diagram of a 1-2 test circuit according to an example embodiment.

Referring to FIGS. 4A, a 1-1 test circuit 111B may include a plurality of resistors R1 and R2 connected to points at which supply voltages VDD1 and VDD2 are applied. Referring to FIG. 4B, a 1-2 test circuit 112B may include a plurality of resistors R3 and R4 connected to points at which supply voltages VDD1 and VDD2 are applied.

The 1-1 test circuit 111B and the 1-2 test circuit 112B may be understood as examples of the 1-1 test circuit 111 and the 1-2 test circuit 112 illustrated in FIG. 1C, respectively.

Therefore, the same or substantially the same components are represented by the same reference numerals, and redundant descriptions are omitted to avoid repetition.

Referring to FIG. 4A, the 1-1 test circuit 111B according to an example embodiment may further include a first resistor R1 and a second resistor R2 connected in series to each other.

For example, the 1-1 test circuit 111B may include a first resistor R1 and a second resistor R2 connected in series to each other and connected to a point at which the first supply voltage VDD1 is applied.

For example, the first resistor R1 may be connected between the point, at which the first supply voltage VDD1 is applied, and the second resistor R2. The second resistor R2 may be connected between the first resistor R1 and ground.

According to an example embodiment, the first supply comparator 231B may compare a magnitude of a first target supply voltage V1, applied to a first node N1 between the first resistor R1 and the second resistor R2, and a magnitude of a first upper reference voltage HR1.

The magnitude of the first target supply voltage V1 may be determined based on a ratio between the magnitude of the first resistor R1 and the magnitude of the second resistor R2. For example, the first target supply voltage V1 may be formed to have a relatively small magnitude compared to the magnitude of the first supply voltage VDD1 generated by the first resistor R1 and the second resistor R2.

For example, the first supply comparator 231B may compare the magnitudes of the first target supply voltage V1 and the first upper reference voltage HR1 to output a first supply test signal STS1.

The second supply comparator 232B may compare the magnitude of the first target supply voltage V1, applied to the first node N1, and a magnitude of a first lower reference voltage LR1.

For example, the second supply comparator 232B may compare the magnitudes of the first target supply voltage V1 and the first lower reference voltage LR1 to output a second supply test signal STS2.

For example, the 1-1 test circuit 111B may determine whether the first target supply voltage V1, formed to have a relatively small magnitude from the first supply voltage VDD1, has a value within a first supply range.

Referring to FIG. 4B, the 1-2 test circuit 112B according to an example embodiment may further include a third resistor R3 and a fourth resistor R4 connected in series to each other.

For example, the 1-2 test circuit 112B may include a third resistor R3 and a fourth resistor R4 connected in series to each other and connected to a point at which the second supply voltage VDD2 is applied.

For example, the third resistor R3 may be connected between a point, at which the second supply voltage VDD2 is applied, and the fourth resistor R4. The fourth resistor R4 may be connected between the third resistor R3 and ground.

According to an example embodiment, the third supply comparator 233B may compare a magnitude of the second target supply voltage V2, applied to a second node N2 between the third resistor R3 and the fourth resistor R4, and a magnitude of the second upper reference voltage HR2.

The magnitude of the second target supply voltage V2 may be determined based on a ratio between the magnitude of the third resistor R3 and the magnitude of the fourth resistor R4. For example, the second target supply voltage V2 may be formed to have a relatively small magnitude compared to the magnitude of the second supply voltage VDD2 generated by the third resistor R3 and the fourth resistor R4.

For example, the third supply comparator 233B may compare the magnitudes of the second target supply voltage V2 and the second upper reference voltage HR2 to output a third supply test signal STS3.

The fourth supply comparator 234B may compare the magnitude of the second target supply voltage V2, applied to the second node N2, and a magnitude of a second lower reference voltage LR2.

For example, the fourth supply comparator 234B may compare the magnitudes of the second target supply voltage V2 and the second lower reference voltage LR2 to output a fourth supply test signal STS4.

For example, the 1-2 test circuit 112B may determine whether the second target supply voltage V2, formed to have a relatively small magnitude from the second supply voltage VDD2, has a value within a second supply range.

Referring to the above-described configurations, the 1-1 test circuit 111B and the 1-2 test circuit 112B may determine whether each of the supply voltages VDD1 and VDD2, input through an electrical path including a plurality of resistors R1, R2, R3, and R4, has a value within a predetermined supply range.

As a result, the system-on-chip 100 or 100A according to an example embodiment may determine whether the target supply voltages V1 and V2, having a smaller magnitude (or a lower level) than the supply voltages VDD1 and VDD2, has a value within a predetermined supply range.

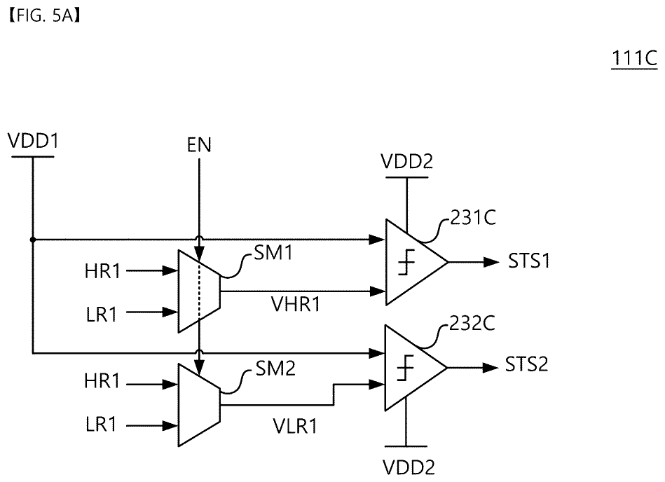

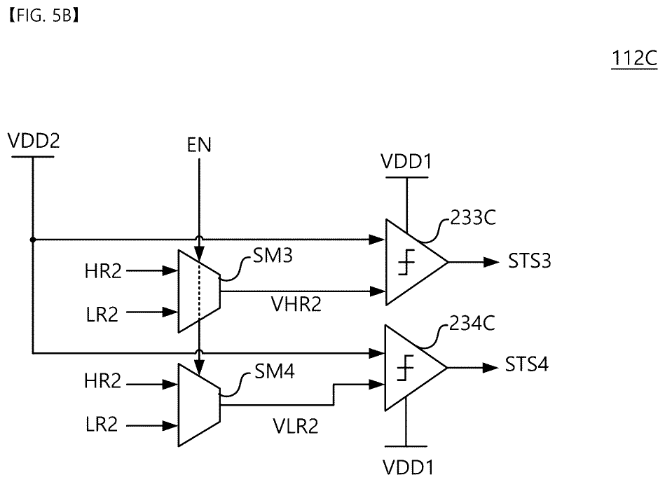

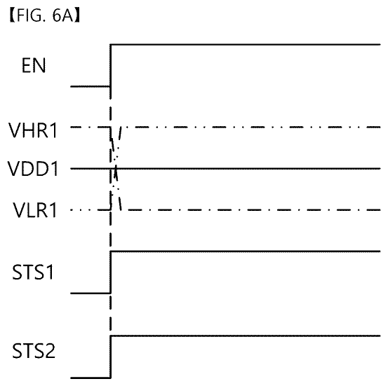

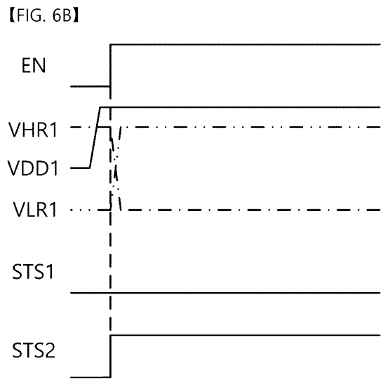

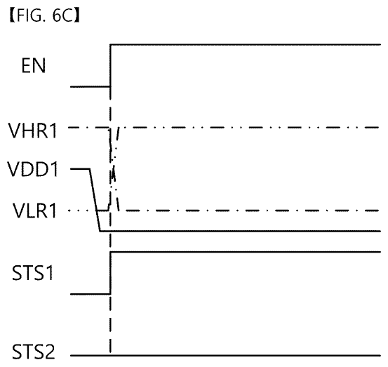

FIG. 5A is a circuit diagram of a 1-1 test circuit according to an example embodiment. FIG. 5B is a circuit diagram of a 1-2 test circuit according to an example embodiment. FIG. 6A is a diagram illustrating signals output by a first test circuit when a first supply voltage according to an example embodiment has a value within a first supply range. FIG. 6B is a diagram illustrating signals output by a first test circuit when a first supply voltage according to an example embodiment has a value exceeding a first supply range. FIG. 6C is a diagram illustrating signals output by a first test circuit when a first supply voltage according to an example embodiment has a value less than a first supply range.

Referring to FIG. 5A, a 1-1 test circuit 111C may include supply multiplexers SM1 and SM2 that operate in response to an enable signal EN. Referring to FIG. 5B, a 1-2 test circuit 112C may include supply multiplexers SM3 and SM4 that operate in response to an enable signal EN.

The 1-1 test circuit 111C and the 1-2 test circuit 112C may be understood as examples of the 1-1 test circuit 111 and the 1-2 test circuit 112 illustrated in FIG. 1C, respectively.

Therefore, the same or substantially the same components are represented by the same reference numerals, and redundant descriptions are omitted to avoid repetition.

Referring to FIG. 5A, the 1-1 test circuit 111C according to an example embodiment may include a first supply multiplexer SM1 and a second supply multiplexer SM2 that operate in response to an enable signal EN.

For example, the 1-1 test circuit 111C may include a first supply multiplexer SM1 that selectively outputs a first upper reference voltage HR1 or a first lower reference voltage LR1 in response to an enable signal EN.

According to an example embodiment, the first supply comparator 231C may compare a first supply voltage VDD1 with a first upper comparison voltage VHR1 output from the first supply multiplexer SM1.

For example, the first supply comparator 231C may compare the magnitudes of the first supply voltage VDD1 and the first upper comparison voltage VHR1, output from the first supply multiplexer SM1, to output a first supply test signal STS1.

For example, referring to FIG. 6a, when a level of the first supply test signal STS1 transitions in response to an enable signal EN, it may be determined that the first supply voltage VDD1 has a value between the first upper reference voltage HR1 and the first lower reference voltage LR1.

For example, referring to FIG. 6B, when the level of the first supply test signal STS1 is maintained before and after the enable signal EN is input, it may be determined that the first supply voltage VDD1 has a value exceeding the first upper reference voltage HR1.

The 1-1 test circuit 111C may include a second supply multiplexer SM2 that selectively outputs the first upper reference voltage HR1 or the first lower reference voltage LR1 in response to an enable signal EN.

According to an example embodiment, the second supply comparator 232C may compare the first supply voltage VDD1 with a first lower comparison voltage VLR1 output from the second supply multiplexer SM2.

For example, the second supply comparator 232C may compare the magnitudes of the first supply voltage VDD1 and the first lower comparison voltage VLR1, output from the second supply multiplexer SM2, to output a second supply test signal STS2.

For example, referring to FIG. 6A, when a level of the second supply test signal STS2 transitions in response to an enable signal EN, it may be determined that the first supply voltage VDD1 has a value between the first upper reference voltage HR1 and the first lower reference voltage LR1.

For example, referring to FIG. 6c, if the level of the second supply test signal STS2 is maintained before and after the enable signal EN is input, it may be determined that the first supply voltage VDD1 has a value less than the first lower reference voltage LR1.

Referring to FIG. 5B, the 1-2 test circuit 112C according to an example embodiment may include a third supply multiplexer SM3 and a fourth supply multiplexer SM4 that operate in response to an enable signal EN.

For example, the 1-2 test circuit 112C may include a third supply multiplexer SM3 that selectively outputs the second upper reference voltage HR2 or the second lower reference voltage LR2 in response to an enable signal EN.

According to an example embodiment, the third supply comparator 233C may compare the second supply voltage VDD2 with a second upper comparison voltage VHR2 output from the third supply multiplexer SM3.

For example, the third supply comparator 233C may compare the magnitudes of the second supply voltage VDD2 and the second upper comparison voltage VHR2, output from the third supply multiplexer SM3, to output the third supply test signal STS3.

For example, the 1-2 test circuit 112C may determine that the second supply voltage VDD2 has a value between the second upper reference voltage HR2 and the second lower reference voltage LR2 when the level of the third supply test signal STS3 transitions in response to an enable signal EN.

For example, the 1-2 test circuit 112C may determine that the second supply voltage VDD2 has a value exceeding the second upper reference voltage HR2 when the level of the third supply test signal STS3 is maintained before and after the enable signal EN is input.

The 1-2 test circuit 112C may include a fourth supply multiplexer SM4 that selectively outputs the second upper reference voltage HR2 or the second lower reference voltage LR2 in response to an enable signal EN.

According to an example embodiment, the fourth supply comparator 234C may compare the second supply voltage VDD2 with the second lower comparison voltage VLR2 output from the fourth supply multiplexer SM4.

For example, the fourth supply comparator 234C may compare the magnitudes of the second supply voltage VDD2 and a second lower comparison voltage VLR2, output from the fourth supply multiplexer SM4, to output a fourth supply test signal STS4.

For example, the 1-2 test circuit 112C may determine that the second supply voltage VDD2 has a value between the second upper reference voltage HR2 and the second lower reference voltage LR2 when a level of the fourth supply test signal STS4 transitions in response to an enable signal EN.

For example, the 1-2 test circuit 112C may determine that the second supply voltage VDD2 has a value less than the second lower reference voltage LR2 when the level of the fourth supply test signal STS4 is maintained before and after the enable signal EN is input.

Referring to the above-described configurations, the 1-1 test circuit 111C and the 1-2 test circuit 112C according to an example embodiment may include the supply multiplexers SM1, SM2, SM3, and SM4 that operate in response to an enable signal EN.

The 1-1 test circuit 111C and the 1-2 test circuit 112C may compare the magnitudes of the voltages, output from the supply multiplexers SM1, SM2, SM3, and SM4, and the supply voltages VDD1 and VDD2 in response to an enable signal EN to determine whether each of the supply voltages VDD1 and VDD2 has a value within a predetermined supply range.

As a result, the system-on-chip 100 or 100A according to an example embodiment may determine whether the first test circuit 110A operates in response to an enable signal EN.

For example, the system-on-chip 100 or 100A may prevent a situation in which, even when an error has occurred in the supply voltages VDD1 and VDD2, the error in the supply voltages VDD1 and VDD2 is not detected due to an error in the first test circuit 110A.

According to the above-described configurations, the system-on-chip 100 or 100A may improve the reliability of the determination of the first test circuit 110A on whether the supply voltages VDD1 and VDD2 have a value within the supply range.

Furthermore, the system-on-chip 100 or 100A according to an example embodiment may improve the accuracy and reliability of a monitoring result for the monitoring voltage VMON output from the monitoring circuit 101 or 101A.

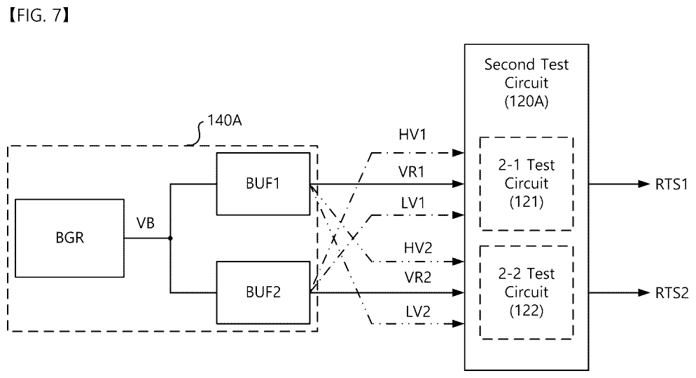

FIG. 7 is a diagram illustrating a configuration in which a second test circuit monitors a first reference voltage and a second reference voltage according to an example embodiment.

Referring to FIG. 7, a second test circuit 120A according to an example embodiment may monitor a first reference voltage VR1 and/or a second reference voltage VR2 based on voltage signals of different levels output from a reference voltage generation circuit 140A.

According to an example embodiment, the reference voltage generation circuit 140A may include a basic voltage generation circuit BGR, a first buffer BUF1, and a second buffer BUF2.

For example, the reference voltage generation circuit 140A may include a basic voltage generation circuit BGR generating a basic voltage VB.

The reference voltage generation circuit 140A may include a first buffer BUF1 generating a first reference voltage VR1 based on the basic voltage VB.

Also, the reference voltage generation circuit 140A may include a second buffer BUF2 generating a second reference voltage VR2 based on the basic voltage VB. For example, the second reference voltage VR2 may have a smaller value than the first reference voltage VR1, but example embodiments are not limited thereto.

According to an example embodiment, the first buffer BUF1 may generate a second upper voltage HV2 and a second lower voltage LV2.

For example, the first buffer BUF1 may generate a second upper voltage HV2 and a second lower voltage LV2, boundary values of a second reference range set for the second reference voltage VR2, based on the basic voltage VB.

The second upper voltage HV2 and the second lower voltage LV2 may have values within a predetermined range from a target value of the second reference voltage VR2.

For example, the second upper voltage HV2 may have a value of 1.05 times the target value of the second reference voltage VR2. For example, the second lower voltage LV2 may have a value of 0.95 times the target value of the second reference voltage VR2.

A 2-2 test circuit 122 according to an example embodiment may determine whether the second reference voltage VR2 has a value between the second upper voltage HV2 and the second lower voltage LV2. For example, the 2-2 test circuit 122 may determine whether the second reference voltage VR2 has a value with an error of less than 5% from the target value.

The second buffer BUF2 according to an example embodiment may generate a first upper voltage HV1 and a first lower voltage LV1.

For example, the second buffer BUF2 may generate a first upper voltage HV1 and a first lower voltage LV1, boundary values of a first reference range set for the first reference voltage VR1, based on the basic voltage VB.

The first upper voltage HV1 and the first lower voltage LV1 may have values within a predetermined range from a target value of the first reference voltage VR1.

For example, the first upper voltage HV1 may have a value of 1.05 times the target value of the first reference voltage VR1. For example, the first lower voltage LV1 may have a value of 0.95 times the target value of the first reference voltage VR1.

A 2-1 test circuit 121 according to an example embodiment may determine whether the first reference voltage VR1 has a value between the first upper voltage HV1 and the first lower voltage LV1. For example, the 2-1 test circuit 121 may determine whether the first reference voltage VR1 has a value with an error of less than 5% from the target value.

Referring to the above-described configurations, a voltage serving as a basis for determining whether one of the two reference voltages VR1 and VR2 has a value within a normal range may be generated from a buffer generating the other reference voltage.

When a buffer generating a reference voltage and a buffer generating a voltage to determine whether the reference voltage has a value within the normal range are distinguished, the impact of an error, occurring in the reference voltage generation buffer, on the monitoring of the reference voltage may be significantly reduced.

For example, the system-on-chip 100 or 100A may distinguish between the buffer generating the reference voltage and the buffer generating the voltage to determine whether the reference voltage is normal, thereby preventing a situation in which, even when an error has occurred in the reference voltage, the error in the reference voltage is not detected due to an error in the buffer generating the reference voltage.

The system-on-chip 100 or 100A according to an example embodiment may significantly reduce the impact of an error, occurring in the buffers BUF1 and BUF2, on the determination on whether an error has occurred in the reference voltages VR1 and VR2.

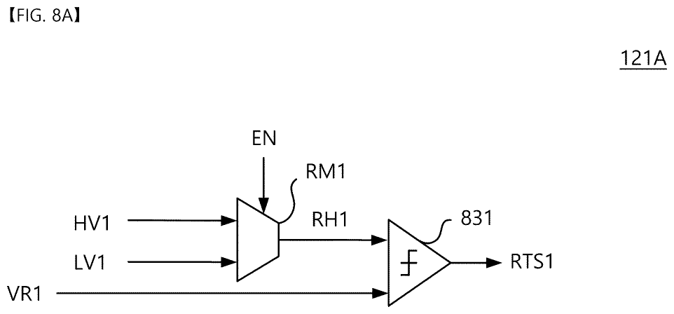

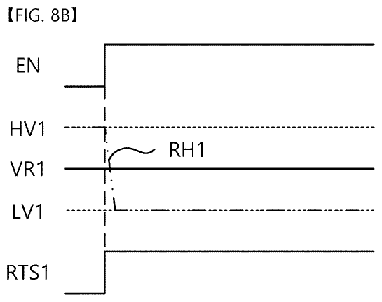

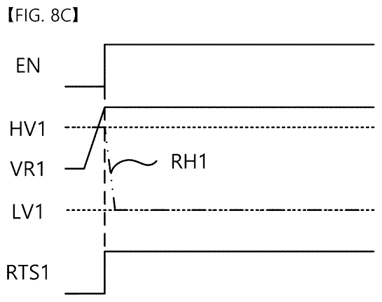

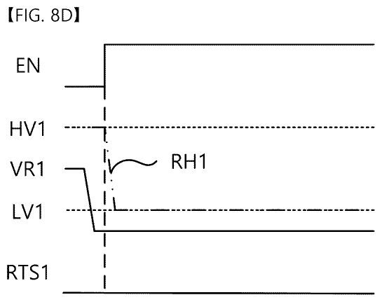

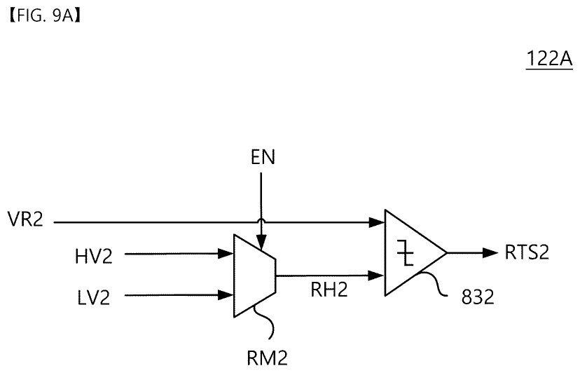

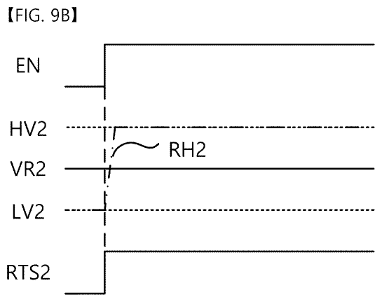

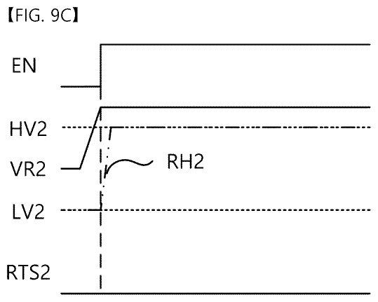

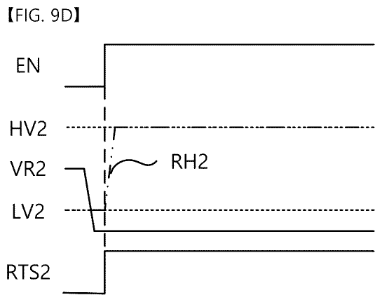

FIG. 8A is a circuit diagram illustrating a configuration of a 2-1 test circuit according to an example embodiment. FIG. 8B is a diagram illustrating signals output by the 2-1 test circuit of FIG. 8A when the first reference voltage has a value between a first upper voltage and a first lower voltage. FIG. 8C is a diagram illustrating signals output by the 2-1 test circuit of FIG. 8A when the first reference voltage has a value greater than or equal to the first upper voltage. FIG. 8D is a diagram illustrating signals output by the 2-1 test circuit of FIG. 8A when the first reference voltage has a value less than or equal to the first lower voltage. FIG. 9A is a circuit diagram illustrating a configuration of a 2-2 test circuit according to an example embodiment. FIG. 9B is a diagram illustrating signals output by the 2-2 test circuit of FIG. 9A when the second reference voltage has a value between a second upper voltage and a second lower voltage. FIG. 9C is a diagram illustrating signals output by the 2-2 test circuit of FIG. 9A when the second reference voltage has a value greater than or equal to the second upper voltage. FIG. 9D is a diagram illustrating signals output by the 2-2 test circuit of FIG. 9A when the second reference voltage has a value less than or equal to the second lower voltage.

Referring to FIGS. 8A and 9A, a 2-1 test circuit 121A and a 2-2 test circuit 122A according to an example embodiment may include reference multiplexers RM1 and RM2 that operate in response to an enable signal EN, respectively.

The 2-1 test circuit 121A and the 2-2 test circuit 122A may be understood as being examples of the 2-1 test circuit 121 and the 2-2 test circuit 122 illustrated in FIG. 7, respectively. Below, operations performed by the 2-1 test circuit 121A and the 2-2 test circuit 122A may be understood as being performed by the second test circuit 120A.

Referring to FIG. 8A, a 2-1 test circuit 121A according to an example embodiment may include a first reference multiplexer RM1 and a first reference comparator 831.

For example, the 2-1 test circuit 121A may include a first reference multiplexer RM1 that selectively outputs a first upper voltage HV1 and a first lower voltage LV1 in response to an enable signal EN.

The first reference multiplexer RM1 according to an example embodiment may output either one of a first upper voltage HV1 and a first lower voltage LV1 as a first reference comparison voltage RH1 in response to an enable signal EN.

For example, referring to FIGS. 8B to 8D, the first reference multiplexer RM1 may output a first upper voltage HV1 as a first reference comparison voltage RH1 while an enable signal EN having a low level is input.

In addition, for example, the first reference multiplexer RM1 may output the first lower voltage LV1 as the first reference comparison voltage RH1 while an enable signal EN having a high level is input.

However, the operation of the first reference multiplexer RM1 is not limited to the above-described example.

The 2-1 test circuit 121A may include a first reference comparator 831 comparing magnitudes of a first reference voltage VR1 and the first reference comparison voltage RH1 output from the first reference multiplexer RM1.

For example, a first reference comparator 831 may compare the magnitudes of the first reference voltage VR1 and the first reference comparison voltage RH1 to output a first reference test signal RTS1.

For example, referring to FIGS. 8B and 8C, the first reference comparator 831 may output a first reference test signal RTS1 having a high level when the first reference voltage VR1 has a value greater than or equal to the first reference comparison voltage RH1.

For example, the 2-1 test circuit 121A may determine that the first reference voltage VR1 has a value between the first upper voltage HV1 and the first lower voltage LV1 when a level of the first reference test signal RTS1, output from the first reference comparator 831, transitions in response to an enable signal EN.

For example, referring to FIG. 8d, the first reference comparator 831 may output a first reference test signal RTS1 having a low level when the first reference voltage VR1 has a value less than the first reference comparison voltage RH1.

The 2-1 test circuit 121A may determine that the first reference voltage VR1 has a value less than and equal to the first lower voltage LV1 when the first reference comparator 831 outputs a first reference test signal RTS1 having a low level.

The 2-1 test circuit 121A may determine that an error has occurred in the first reference voltage VR1 when the first reference comparator 831 outputs a first reference test signal RTS1 having a low level.

For example, the 2-1 test circuit 121A may determine that the first reference voltage VR1 has a value less than or equal to the first lower voltage LV1 when a level of the first reference test signal RTS1, output from the first reference comparator 831, is maintained in response to an enable signal EN.

Referring to FIG. 9A, a 2-2 test circuit 122A according to an example embodiment may include a second reference multiplexer RM2 and a second reference comparator 832.

For example, the 2-2 test circuit 122A may include a second reference multiplexer RM2 that selectively outputs a second upper voltage HV2 and a second lower voltage LV2 in response to an enable signal EN.

According to an example embodiment, the second reference multiplexer RM2 may output either one of a second upper voltage HV2 and a second lower voltage LV2 as a second reference comparison voltage RH2 in response to an enable signal EN.

For example, referring to FIGS. 9B to 9D, the second reference multiplexer RM2 may output the second lower voltage LV2 as the second reference comparison voltage RH2 while an enable signal EN having a low level is input.

In addition, for example, the second reference multiplexer RM2 may output the second upper voltage HV2 as the second reference comparison voltage RH2 while an enable signal EN having a high level is input.

However, the operation of the second reference multiplexer RM2 is not limited to the above-described example.

The 2-2 test circuit 122A may include a second reference comparator 832 comparing magnitudes of a second reference voltage VR2 and the second reference comparison voltage RH2 output from the second reference multiplexer RM2.

For example, the second reference comparator 832 may compare the magnitudes of the second reference voltage VR2 and the second reference comparison voltage RH2 to output a second reference test signal RTS2.

For example, referring to FIGS. 9B and 9D, the second reference comparator 832 may output a second reference test signal RTS2 having a high level when the second reference voltage VR2 has a value less than the second reference comparison voltage RH2.

For example, referring to FIG. 9C, the second reference comparator 832 may output a second reference test signal RTS2 having a low level when the second reference voltage VR2 has a value greater than or equal to the second reference comparison voltage RH2.

The 2-2 test circuit 122A may determine that the second reference voltage VR2 has a value greater than or equal to the second upper voltage HV2 when the second reference comparator 832 outputs a second reference test signal RTS2 having a low level.

For example, the 2-2 test circuit 122A may determine that an error has occurred in the second reference voltage VR2 when the second reference comparator 832 outputs a second reference test signal RTS2 having a low level.

Referring to the above-described configurations, the 2-1 test circuit 121A and the 2-2 test circuit 122A according to an example embodiment may include reference multiplexers RM1 and RM2 that operates in response to an enable signal EN, respectively.

In addition, the 2-1 test circuit 121A and the 2-2 test circuit 122A may compare the magnitudes of voltages, output from the reference multiplexers RM1 and RM2, and the reference voltages VR1 and VR2 in response to an enable signal EN to determine whether each of the reference voltages VR1 and VR2 has a value within a predetermined reference range.

As a result, the system-on-chip 100 or 100A according to an example embodiment may determine whether an error has occurred in the reference voltages VR1 and VR2 used for the monitoring circuit 101 or 101A to determine whether a monitoring voltage VMON has a value within a normal range.

In addition, the system-on-chip 100 or 100A according to an example embodiment may determine whether the second test circuit 120A operates in response to an enable signal EN.

For example, the system-on-chip 100 or 100A may prevent a situation in which, even when an error has occurred in the reference voltages VR1 and VR2, the error in the reference voltages VR1 and VR2 is not detected due to an error in the second test circuit 120A.

As a result, the system-on-chip 100 or 100A may improve the reliability of the determination of the second test circuit 120A on whether the reference voltages VR1 and VR2 has a value within a predetermined reference range.

Furthermore, the system-on-chip 100 or 100A according to an example embodiment may improve the accuracy and reliability of monitoring result for the monitoring voltage VMON output from the monitoring circuit 101 or 101A.

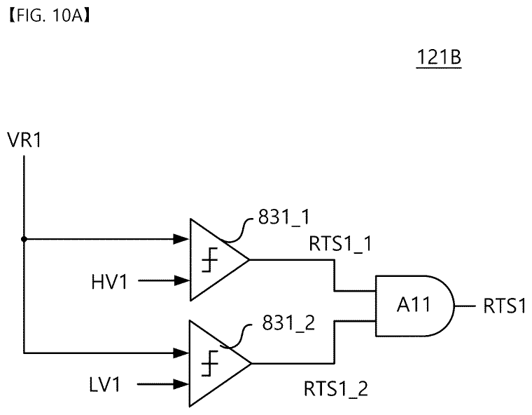

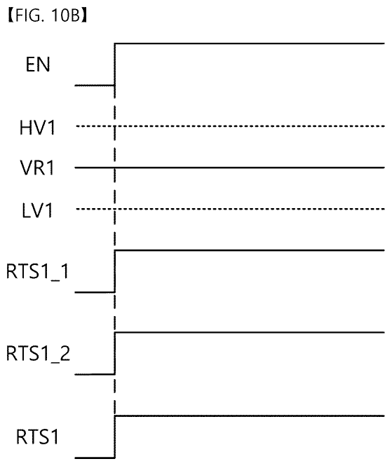

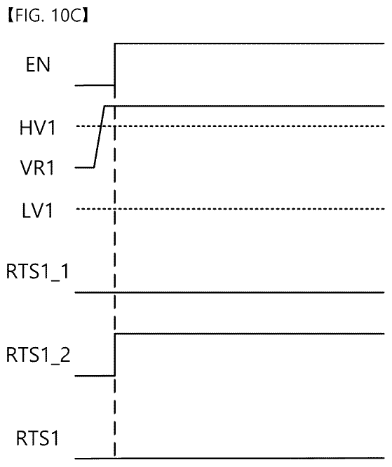

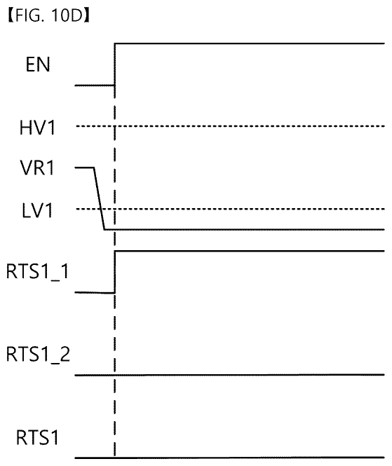

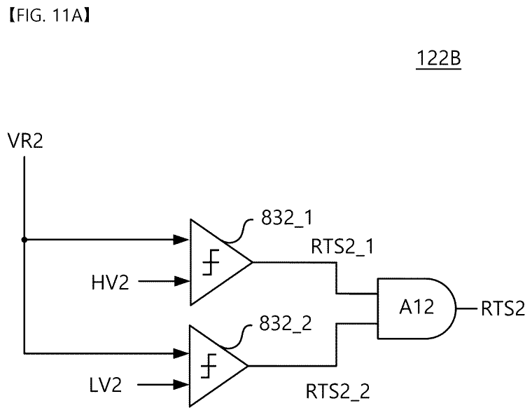

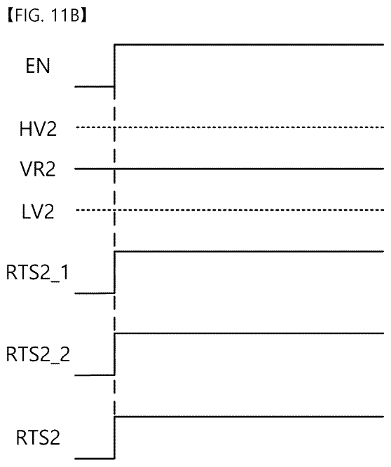

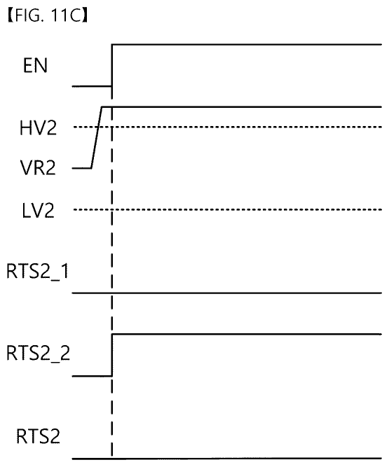

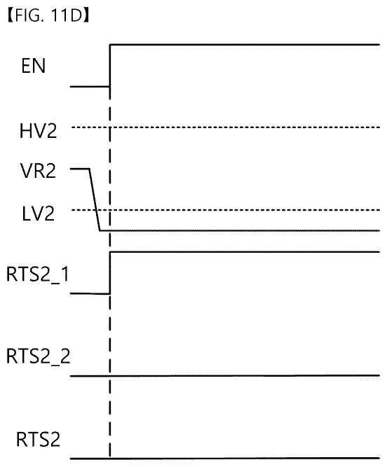

FIG. 10A is a circuit diagram illustrating a configuration of a 2-1 test circuit according to an example embodiment. FIG. 10B is a diagram illustrating signals output by the 2-1 test circuit of FIG. 10A when a first reference voltage has a value between a first upper voltage and a first lower voltage. FIG. 10C is diagram illustrating signals output by the 2-1 test circuit of FIG. 10A when the first reference voltage has a value greater than or equal to the first upper voltage. FIG. 10D is a diagram illustrating signals output by the 2-1 test circuit of FIG. 10A when the first reference voltage has a value less than or equal to the first lower voltage. FIG. 11A is a circuit diagram illustrating a configuration of a 2-2 test circuit according to an example embodiment. FIG. 11B is a diagram illustrating signals output by the 2-2 test circuit of FIG. 11A when a second reference voltage has a value between a second upper voltage and a second lower voltage. FIG. 11C is a diagram illustrating signals output by the 2-2 test circuit of FIG. 11A when a second reference voltage has a value greater than or equal to the second upper voltage. FIG. 11D is a diagram illustrating signals output by the 2-2 test circuit of FIG. 11A when the second reference voltage has a value less than or equal to the second lower voltage.

Referring to FIGS. 10A and 11B, a 2-1 test circuit 121B and a 2-2 test circuit 122B according to an example embodiment may include a plurality of comparators 831_1 and 831_2 and a plurality of comparators 832_1 and 832_2 and AND gates A11 and A12, respectively.

The 2-1 test circuit 121B and the 2-2 test circuit 122B may be understood as being examples of the 2-1 test circuit 121 and the 2-2 test circuit 122 illustrated in FIG. 7, respectively. Below, operations performed by the 2-1 test circuit 121B and the 2-2 test circuit 122B may be understood as being performed by the second test circuit 120A.

Referring to FIG. 10A, the 2-1 test circuit 121B according to an example embodiment may include a 1-1 reference comparator 831_1, a 1-2 reference comparator 831_2, and a first reference AND gate A11.

For example, the 2-1 test circuit 121B may include a 1-1 reference comparator 831_1 comparing magnitudes of a first reference voltage VR1 and a first upper voltage HV1.

According to an example embodiment, the 1-1 reference comparator 831_1 may compare magnitudes of the first reference voltage VR1 and the first upper voltage HV1 to output a 1-1 reference test signal RTS1_1.

For example, referring to FIGS. 10B and 10D, the 1-1 reference comparator 831_1 may output a 1-1 reference test signal RTS1_1 having a high level when the first reference voltage VR1 has a value less than the first upper voltage HV1.

For example, referring to FIG. 10C, the 1-1 reference comparator 831_1 may output a 1-1 reference test signal RTS1_1 having a low level when the first reference voltage VR1 has a value greater than or equal to the first upper voltage HV1.

The 2-1 test circuit 121B may include a 1-2 reference comparator 831_2 comparing magnitudes of the first reference voltage VR1 and a first lower voltage LV1.

According to an example embodiment, the 1-2 reference comparator 831_2 may compare the magnitudes of the first reference voltage VR1 and the first lower voltage LV1 to output a 1-2 reference test signal RTS1_2.

For example, referring to FIGS. 10B and 10C, the 1-2 reference comparator 831_2 may output a 1-2 reference test signal RTS1_2 having a high level when the first reference voltage VR1 has a value exceeding the first lower voltage LV1.

For example, referring to FIG. 10D, the 1-2 reference comparator 831_2 may output a 1-2 reference test signal RTS1_2 having a low level when the first reference voltage VR1 has a value less than or equal to the first lower voltage LV1.

The 2-1 test circuit 121B may include a first reference AND gate A11 performing a logical AND operation on the 1-1 reference test signal RTS1_1 and the 1-2 reference test signal RTS1_2.

For example, the first reference AND gate A11 may perform a logical AND operation on the 1-1 reference test signal RTS1_1 and the 1-2 reference test signal RTS1_2 to output a first reference test signal RTS1.

For example, referring to FIG. 10B, the first reference AND gate All may output a first reference test signal RTS1 having a high level when both the 1-1 reference test signal RTS1_1 and the 1-2 reference test signal RTS1_2 have a high level.

For example, referring to FIGS. 10C and 10D, the first reference AND gate A11 may output a first reference test signal RTS1 having a low level when either one of the 1-1 reference test signal RTS1_1 and the 1-2 reference test signal RTS1_2 has a low level.

Furthermore, the 2-1 test circuit 121B may determine that an error has occurred in the first reference voltage VR1 when the first reference AND gate A11 outputs a first reference test signal RTS1 having a low level.

Referring to FIG. 11A, the 2-2 test circuit 122B according to an example embodiment may include a 2-1 reference comparator 832_1, a 2-2 reference comparator 832_2, and a second reference AND gate A12.

For example, the 2-2 test circuit 122B may include a 2-1 reference comparator 832_1 comparing magnitudes of the second reference voltage VR2 and the second upper voltage HV2.

According to an example embodiment, the 2-1 reference comparator 832_1 may compare the magnitudes of the second reference voltage VR2 and the second upper voltage HV2 to output a 2-1 reference test signal RTS2_1.

For example, referring to FIGS. 11B and 11D, the 2-1 reference comparator 832_1 may output a 2-1 reference test signal RTS2_1 having a high level when the second reference voltage VR2 has a value less than the second upper voltage HV2.

For example, referring to FIG. 11C, the 2-1 reference comparator 832_1 may output a 2-1 reference test signal RTS2_1 having a low level when the second reference voltage VR2 has a value greater than or equal to the second upper voltage HV2.

The 2-2 test circuit 122B may include a 2-2 reference comparator 832_2 comparing the magnitudes of the second reference voltage VR2 and the second lower voltage LV2.

According to an example embodiment, the 2-2 reference comparator 832_2 may compare the magnitudes of the second reference voltage VR2 and the second lower voltage LV2 to output a 2-2 reference test signal RTS2_2.

For example, referring to FIGS. 11B and 11C, the 2-2 reference comparator 832_2 may output a 2-2 reference test signal RTS2_2 having a high level when the second reference voltage VR2 has a value exceeding the second lower voltage LV2.

For example, referring to FIG. 11D, the 2-2 reference comparator 832_2 may output a 2-2 reference test signal RTS2_2 having a low level when the second reference voltage VR2 has a value less than or equal to the second lower voltage LV2.

The 2-2 test circuit 122B may include a second reference AND gate A12 performing a logical AND operation on the 2-1 reference test signal RTS2_1 and the 2-2 reference test signal RTS2_2.

For example, the second reference AND gate A12 may perform a logical AND operation on the 2-1 reference test signal RTS2_1 and the 2-2 reference test signal RTS2_2 to output a second reference test signal RTS2.

For example, referring to FIG. 11B, the second reference AND gate A12 may output a second reference test signal RTS2 having a high level when both the 2-1 reference test signal RTS2_1 and the 2-2 reference test signal RTS2_2 have a high level.

For example, referring to FIGS. 11C and 11D, the second reference AND gate A12 may output a second reference test signal RTS2 having a low level when either of the 2-1 reference test signal RTS2_1 and the 2-2 reference test signal RTS2_2 has a low level.

Furthermore, the 2-2 test circuit 122B may determine that an error has occurred in the second reference voltage VR2 when the second reference AND gate A12 outputs a second reference test signal RTS2 having a low level.

Referring to the above-described configurations, the 2-1 test circuit 121B and the 2-2 test circuit 122B may determine whether the first reference voltage VR1 and the second reference voltage VR2 have values within the preset reference range, respectively.

As a result, the system-on-chip 100 or 100A according to an example embodiment may improve the accuracy and reliability of monitoring results for the monitoring voltage VMON output from the monitoring circuit 101 or 101A.

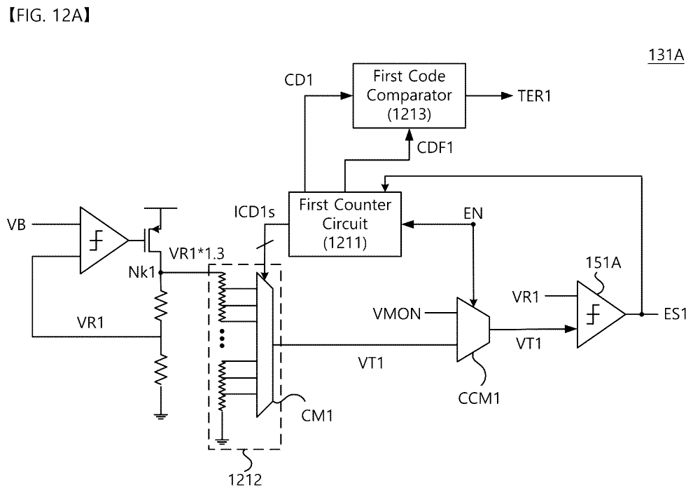

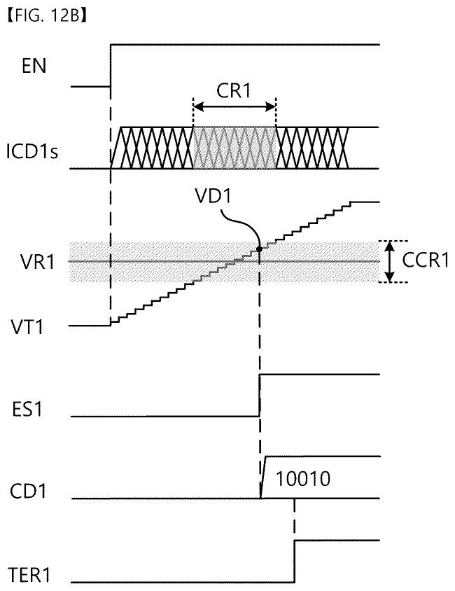

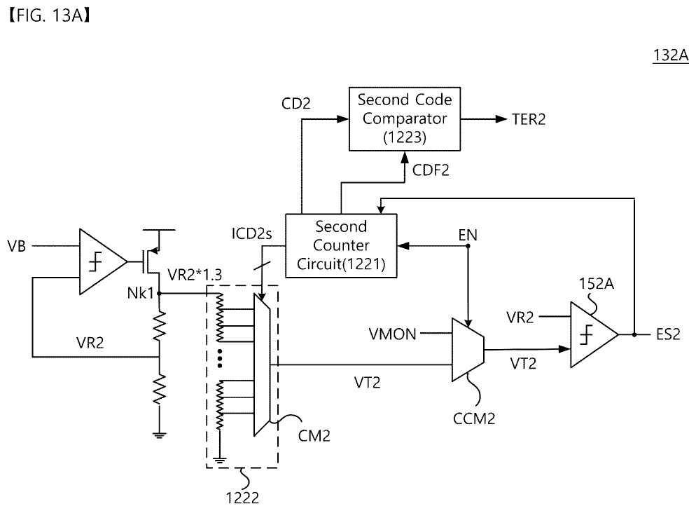

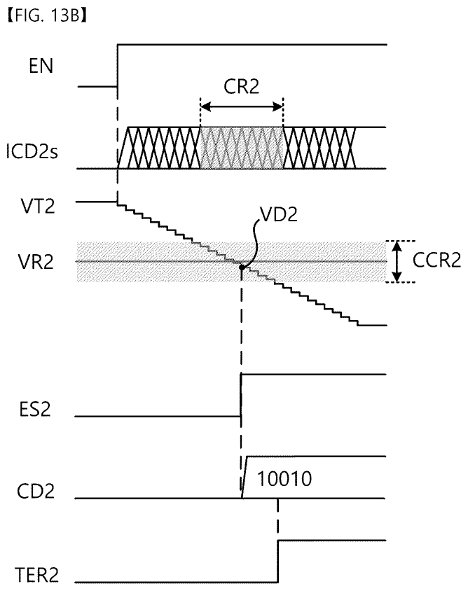

FIG. 12A is a circuit diagram illustrating a configuration of a 3-1 test circuit according to an example embodiment. FIG. 12B is a diagram illustrating a configuration in which the 3-1 test circuit of FIG. 12A outputs a first comparison test signal. FIG. 13A is a circuit diagram illustrating a configuration of a 3-2 test circuit according to an example embodiment. FIG. 13B is a diagram illustrating a configuration in which the 3-2 test circuit of FIG. 13A outputs a second comparison test signal.

Referring to FIG. 12A, a 3-1 test circuit 131A according to an example embodiment may include a first counter circuit 1211, a first converter circuit 1212, and a first code comparator 1213.

The 3-1 test circuit 131A may be understood as an example of the 3-1 test circuit 131 illustrated in FIG. 1C.

For example, the 3-1 test circuit 131A may include a first counter circuit 1211 that sequentially outputs first input codes ICDIs increasing by a unit code at a specified period.

The first counter circuit 1211 according to an example embodiment may increase first input codes ICDIs having a specified number of bits by a unit code at a specified period and then sequentially output the increased first input codes.

For example, the first counter circuit 1211 may increase first input codes ICD1s each consisting of 5 bits from “00000” to “11111” at a specified period and then sequentially output the increased first input codes, in response to an enable signal EN.

However, the number of bits and the configuration of the first input codes ICD1s output by the first counter circuit 1211 are not limited to the above-described example.

The 3-1 test circuit 131A may include a first converter circuit 1212 increasing a magnitude of the first test voltage VT1 by a unit voltage at a specified period and then outputting the increased magnitude of the first test voltage VT1, in response to each of the first input codes ICD1s.

Referring to FIGS. 12A and 12B, the first converter circuit 1212 may increase the magnitude of the first test voltage VT1 by a unit voltage and then output the increased magnitude of the first test voltage VT1, in response to each of the first input codes ICD1s input from the first counter circuit 1211.

For example, the first converter circuit 1212 may include a first converting multiplexer CM1 connected to a plurality of resistors.

Accordingly, the first converter circuit 1212 may control the first converting multiplexer CM1 such that the first converting multiplexer CM1 outputs the first test voltage VT1 having a magnitude corresponding to input first input codes ICD1s.

For example, the first converter circuit 1212 may control the first converting multiplexer CM1 to reduce a magnitude of a resistor connected between the first converting multiplexer CM1 and a first output node Nk1, at which a voltage having a value obtained by multiplying a first reference voltage VR1 by a specified factor (for example, 1.3), as the input first input codes ICD1s increase.

For example, the first converter circuit 1212 may control the first converting multiplexer CM1 to increase the first test voltage VT1 by a unit voltage and then output the increased first test voltage, as the input first input codes ICD1s increase by a unit code.

For example, the first converter circuit 1212 may output the first test voltage VT1 to have a value of 80% of a target value of the first reference voltage VR1 in response to the input code “00000.”

The first converter circuit 1212 may increase the magnitude of the first test voltage VT1 to have a value of 120% of the target value of the first reference voltage VR1 as an input code increases from “00000” to “11111.”

The target value of the first reference voltage VR1 may be a magnitude value of the first reference voltage VR1 set for an ideal operation of the monitoring circuit 101 or 101A, and may be understood as a value stored in the system-on-chip 100 or 100A.

The 3-1 test circuit 131A may include a first comparison multiplexer CCM1, selectively outputting either one of the monitoring voltage VMON and the first test voltage VT1 in response to an enable signal EN.

For example, the first comparison multiplexer CCM1 may output the first test voltage VT1 in response to an enable signal EN having a high level being input.

For example, the first comparison multiplexer CCM1 may output the monitoring voltage VMON in response to an enable signal EN having a low level being input.

The 3-1 test circuit 131A may include a first comparator 151A comparing magnitudes of the first test voltage VT1 and the first reference voltage VR1. The first comparator 151A may be understood as an example of the first comparator 151 illustrated in FIG. 1A.

For example, the first comparator 151A may compare the magnitudes of the first test voltage VT1 and the first reference voltage VR1 to output a first error signal ES1.

For example, referring to FIG. 12B, the first comparator 151A according to an example embodiment may output a first error signal ES1 having a high level when the first reference voltage VR1 has a value less than or equal to the first test voltage VT1.

According to an example embodiment, the first counter circuit 1211 may transmit a first code CD1 corresponding to the first test voltage VT1 to the first code comparator 1213 at a time point at which the first comparator 151A determines that the first reference voltage VR1 is less than or equal to the first test voltage VT1.

For example, the first code CD1 may be understood as a code output from the first counter circuit 1211 to output the first test voltage VT1 determined to have the same value as the first reference voltage VR1 by the first comparator 151A.

The first counter circuit 1211 may transmit the first code CD1, output to generate the first test voltage VT1 determined to have the same value as the first reference voltage VR1 by the first comparator 151A, to the first code comparator 1213.

For example, the first counter circuit 1211 may transmit the code “10010,” output to generate the first test voltage VT1 determined to have the same value as the first reference voltage VR1 by the first comparator 151A, to the first code comparator 1213.

In addition, the first counter circuit 1211 may transmit a first entire code CDF1, including codes output by the first converter circuit 1212, to the first code comparator 1213.

The 3-1 test circuit 131A may include a first code comparator 1213 determining whether a value of the first code CD1 falls within a predetermined first code range CR1.

According to an example embodiment, the first code comparator 1213 may determine whether the first code CD1 has a value within a predetermined first code range CR1, based on the first entire code CDF1 and the first code CD1 output from the first counter circuit 1211.

For example, the first code comparator 1213 may determine whether the code “10010,” obtained from the first counter circuit 1211, has a value within the predetermined code range from “01100” to “10010.”

Referring to FIG. 12b according to an example embodiment, when the first code CD1 has a value within the first code range, the first code comparator 1213 may output a first comparison test signal TER1 having a high level.

The 3-1 test circuit 131A may determine that the first comparator 151A compares the monitoring voltage VMON with a first determination voltage VD1 having a value within the first comparison range CCR1 from the first reference voltage VR1 to output a first error signal ES1.

For example, the 3-1 test circuit 131A may determine that the first comparator 151A compares the monitoring voltage VMON with the first reference voltage VR1 having an offset (or error) less than the predetermined first comparison range CCR1 in response to a first comparison test signal TER1 having a high level.

According to an example embodiment, when the first code CD1 has a value outside the first code range, the first code comparator 1213 may output a first comparison test signal TER1 having a low level.

The 3-1 test circuit 131A may determine that the first comparator 151A compare the monitoring voltage VMON with a voltage having a value outside the first comparison range CCR1 from the first reference voltage VR1 to output an error signal ES1.

For example, the 3-1 test circuit 131A may determine that the first comparator 151A compares the monitoring voltage VMON with the first reference voltage VR1 having an offset (or error) exceeding the predetermined first comparison range CCR1 in response to the first comparison test signal TER1 having a low level.

Referring to the above-described configurations, the 3-1 test circuit 131A may determine whether the first comparator 151A monitors the monitoring voltage VMON with an offset less than a predetermined value.

Referring to FIG. 13A, the 3-2 test circuit 132A according to an example embodiment may include a second counter circuit 1221, a second converter circuit 1222, and a second code comparator 1223.

The 3-2 test circuit 132A may be understood as an example of the 3-2 test circuit 132 illustrated in FIG. 1C.

For example, the 3-2 test circuit 132A may include a second counter circuit 1221 that sequentially outputs second input codes ICD2s decreasing by a unit code at a specified period.

According to an example embodiment, the second counter circuit 1221 may decrease second input codes ICD2s having a specified number of bits by a unit code at a specified period and then sequentially output the decreased second input codes.

For example, the second counter circuit 1221 may sequentially output second input codes ICD2s consisting of 5 bits while decreasing the second input codes ICD2s from “11111” to “00000” at a specified period, in response to an enable signal EN.

However, the number of bits and configuration of the second input codes ICD2s, output by the second counter circuit 1221, are not limited to the above-described example.

In addition, the 3-2 test circuit 132A may include a second converter circuit 1222 decreasing a magnitude of the second test voltage VT2 by a unit voltage at a specified period and then output the decreased magnitude of the second test voltage VT2, in response to each of the second input codes ICD2s.

Referring to FIGS. 13A and 13B, the second converter circuit 1222 may output the magnitude of the second test voltage VT2 while decreasing the magnitude of the second test voltage VT2 by a unit voltage, in response to each of the second input codes ICD2s input from the second counter circuit 1221.

For example, the second converter circuit 1222 may include a second converting multiplexer CM2 connected to a plurality of resistors.

Accordingly, the second converter circuit 1222 may control the second converting multiplexer CM2 such that the second converting multiplexer CM2 outputs a second test voltage VT2 having a size corresponding to input second input codes ICD2s.

For example, the second converter circuit 1222 may control the second converting multiplexer CM2 to increase a magnitude of a resistor connected between the second converting multiplexer CM2 and a second output node Nk2, at which a voltage having a value obtained by multiplying a second reference voltage VR2 by a specified factor (for example, 1.3), as the input second input codes ICD2s decrease.

For example, the second converter circuit 1222 may decrease the second voltage VT2 by a unit voltage and then output the decreased second voltage as the input second input codes ICD2s decrease by a unit code by controlling the second converting multiplexer MC2.

For example, the second converter circuit 1222 may output the second test voltage VT2 to have a value of 120% of a target value of the second reference voltage VR2 in response to the input code “11111.”

In addition, the second converter circuit 1222 may decrease and output the magnitude of the second test voltage VT2 to have 80% of a target value of the second reference voltage VR2 as the input code decreases sequentially from “11111” to “00000.”

For example, the target value of the second reference voltage VR2 may be a magnitude value of the second reference voltage VR2 set for an ideal operation of the monitoring circuit 101 or 101A, and may be understood as a value stored in the system-on-chip 100 or 100A.

In addition, the 3-2 test circuit 132A may include a second comparison multiplexer CCM2 that selectively outputs either of the monitoring voltage VMON and the second test voltage VT2 in response to an enable signal EN.

For example, the second comparison multiplexer CCM2 may output the second test voltage VT2 in response to an enable signal EN having a high level.

For example, the second comparison multiplexer CCM2 may output the monitoring voltage VMON in response to an enable signal EN having a low level.

In addition, the 3-2 test circuit 132A may include a second comparator 152A comparing a magnitude of the second test voltage VT2 with the second reference voltage VR2. The second comparator 152A may be understood as an example of the second comparator 152 illustrated in FIG. 1A.

For example, the second comparator 152A may compare the magnitude of the second test voltage VT2 with the second reference voltage VR2 to output a second error signal ES2.

For example, referring to FIG. 13B, the second comparator 152A according to an example embodiment may output a second error signal ES2 having a high level when the second reference voltage VR2 has a value greater than or equal to the second test voltage VT2.

According to an example embodiment, the second counter circuit 1221 may transmit the second code CD2 corresponding to the second test voltage VT2 to the second code comparator 1223 at a time point at which the second comparator 152A determines that the second reference voltage VR2 is greater than or equal to the second test voltage VT2.

For example, the second code CD2 may be understood as a code output from the second counter circuit 1221 to output a second test voltage VT2, determined to have the same value as the second reference voltage VR2 by the second comparator 152A, among the code input codes ICD2s.

The second counter circuit 1221 may transmit the second code CD2, output to generate the second test voltage VT2 determined to have the same value as the second reference voltage VR2 by the second comparator 152A, to the second code comparator 1223.

For example, the second counter circuit 1221 may transmit the code “10010,” output to generate the second test voltage VT2 determined to have the same value as the second reference voltage VR2 by the second comparator 152A, to the second code comparator 1223.

In addition, the second counter circuit 1221 may transmit a second entire code CDF2, including codes output to the second converter circuit 1222, to the second code comparator 1223.

The 3-2 test circuit 132A may include a second code comparator 1223 determining whether a value of the second code CD2 falls within a predetermined second code range CR2.

According to an example embodiment, the second code comparator 1223 may determine whether the second code CD2 has a value within the predetermined second code range CR2, based on the second entire code CDF2 and the second code CD2 output from the second counter circuit 1221.

For example, the second code comparator 1223 may determine whether the code “10010” obtained from the second counter circuit 1221 has a value within the predetermined code range from “01100” to “10010.”

Referring to FIG. 13B according to an example embodiment, when the second code CD2 has a value within the second code range, the second code comparator 1223 may output a second comparison test signal TER2 having a high level.

The 3-2 test circuit 132A may determine that the second comparator 152A may compare the monitoring voltage VMON with the second determination voltage VD2, having a value within the second comparison range CCR2 from the second reference voltage VR2, to outputs an error signal ES2.

For example, the 3-2 test circuit 132A may determine that the second comparator 152A compares the monitoring voltage VMON with the second reference voltage VR2 having an offset (or error) less than the predetermined second comparison range CCR2 in response to the second comparison test signal TER2 having a high level.

According to an example embodiment, when the second code CD2 has a value outside the second code range, the second code comparator 1223 may output a second comparison test signal TER2 having a low level.

The 3-2 test circuit 132A may determine that the second comparator 152A compare the monitoring voltage VMON with a voltage, having a value outside the second comparison range CCR2 from the second reference voltage VR2, to output a second error signal ES2.

For example, the 3-2 test circuit 132A may determine that the second comparator 152A compares the monitoring voltage VMON with the second reference voltage VR2, having an offset (or error) exceeding the predetermined second comparison range CCR2, in response to the low-level second comparison test signal TER2.

Referring to the above-described configurations, the 3-2 test circuit 132A may determine whether the second comparator 152A monitors the monitoring voltage VMON with an offset less than a predetermined value.

As described above, the system-on-chip 100 or 100A may determine whether the comparators 151A and 152A of the monitoring circuit 101 or 101A operate with an offset (or error) less than a specified value.

As a result, the system-on-chip 100 or 100A according to an example embodiment may improve the accuracy and reliability of monitoring result for the monitoring voltage VMON output from the monitoring circuit 101 or 101A.

As described above, the BIST circuit 102 or 102A according to an example embodiment may determine whether each of the supply voltages VDD1 and VDD2, input to the monitoring circuit 101 or 101A, has a value within the predetermined supply range. In addition, the BIST circuit 102 or 102A may determine whether each of the reference voltages VR1 and VR2 for monitoring the monitoring voltage VMON has a value within the preset reference range. In addition, the BIST circuit 102 or 102A may determine whether the comparators 151 and 152 of the monitoring circuit 101 or 101A operate with an offset less than a specified value.

As a result, the system-on-chip 100 or 100A according to an example embodiment may accurately determine whether the monitoring circuit 101 or 101A is operating normally.

Furthermore, the system-on-chip 100 or 100A according to an example embodiment may improve the accuracy and reliability of monitoring result for the monitoring voltage VMON output from the monitoring circuit 101 or 101A.

As set forth above, a system-on-chip (SoC) according to example embodiments may improve the accuracy and reliability of a result of monitoring a monitoring voltage, output from a monitoring circuit, using a BIST circuit.

While example embodiments have been shown and described above, it will be apparent to those skilled in the art that modifications and variations could be made without departing from the scope of the present inventive concept as defined by the appended claims.

What is claimed is:

1. A system-on-chip (SoC) comprising:
a monitoring circuit configured to determine whether a monitoring voltage has a value between a first reference voltage and a second reference voltage using a first supply voltage and a second supply voltage; and
a built-in self-test (BIST) circuit configured to, in response to an enable signal, determine whether the monitoring circuit is operating normally,
wherein:
the BIST circuit comprises:
a first test circuit configured to determine whether the first supply voltage has a value within a predetermined first supply range using the second supply voltage;
a second test circuit configured to determine whether the first reference voltage has a value within a predetermined first reference range; and
a third test circuit configured to determine whether the monitoring circuit compares a magnitude of the monitoring voltage with a magnitude of a first determination voltage having a value within a predetermined first comparison range from the first reference voltage.

2. The SoC of claim 1, wherein:
the monitoring circuit comprises:
a reference voltage generation circuit configured to generate the first reference voltage and the second reference voltage;
a first comparator configured to compare the magnitude of the monitoring voltage with a magnitude of the first reference voltage; and
a second comparator configured to compare the magnitude of the monitoring voltage and a magnitude of the second reference voltage.

3. The SoC of claim 2, wherein:
the reference voltage generation circuit is configured to output a first upper reference voltage and a first lower reference voltage, each having a value within a predetermined range from a previously stored target value of the first supply voltage,
the first test circuit comprises:
a first supply comparator configured to compare the first supply voltage and the first upper reference voltage; and
a second supply comparator configured to compare the first supply voltage and the first lower reference voltage, and
the first supply comparator and the second supply comparator are configured to operate using the second supply voltage.

4. The SoC of claim 3, wherein:
the first test circuit further comprises a first resistor and a second resistor connected in series to each other and connected to a point at which the first supply voltage is configured to be applied, and
the first supply comparator is configured to compare a magnitude of the first target supply voltage, applied to a first node between the first resistor and the second resistor, and the magnitude of the first reference voltage.

5. The SoC of claim 2, wherein:
the reference voltage generation circuit comprises:
a basic voltage generation circuit configured to generate a basic voltage;
a first buffer configured to generate the first reference voltage based on the basic voltage; and
a second buffer configured to generate the second reference voltage based on the basic voltage, and
the second test circuit is configured to determine whether the first reference voltage has a value between a first upper voltage and a first lower voltage output from the second buffer.

6. The SoC of claim 5, wherein:
the second test circuit further comprises:
a first reference multiplexer configured to selectively output one of the first upper voltage and the first lower voltage based on the enable signal; and
a first reference comparator configured to compare a magnitude of a voltage, output from the first reference multiplexer, and the magnitude of the first reference voltage, and
the second test circuit is configured to determine that the first reference voltage has a value between the first upper voltage and the first lower voltage when a level of a first reference test signal transitions, in response to the enable signal.

7. The SoC of claim 5, wherein:
the second test circuit is configured to determine whether the second reference voltage has a value between the second upper voltage and the second lower voltage output from the first buffer.

8. The SoC of claim 7, wherein:
the second test circuit further comprises:
a 2-1 reference comparator configured to determine whether the second reference voltage is greater than or equal to the second upper voltage; and
a 2-2 reference comparator configured to determine whether the second reference voltage is less than or equal to the second lower voltage.

9. The SoC of claim 3, wherein:
the first test circuit comprises a first supply multiplexer configured to selectively output one of the first upper reference voltage and the first lower reference voltage based on the enable signal,
the first supply comparator is configured to compare magnitudes of a first upper comparison voltage, output from the first supply multiplexer, and the first supply voltage, and
the first test circuit is configured to determine that the first supply voltage has a value between the first upper reference voltage and the first lower reference voltage when a level of a first supply test signal output from the first supply comparator transitions, in response to the enable signal.

10. The SoC of claim 2, wherein:
the third test circuit comprises:
a first counter circuit configured to sequentially output first input codes increasing by a unit code at a specified period;
a first converter circuit configured to increase a magnitude of a first test voltage by a unit voltage at the specified period and then output the increased magnitude of the first test voltage, in response to the first input code; and
a first code comparator configured to determine whether a value of a first code, output to generate the first test voltage determined to have a same value as the first reference voltage by the first comparator, falls within a previously stored first code range, and
the third test circuit is configured to determine that the first comparator compares the monitoring voltage with the first determination voltage, having a value within the first comparison range from the first reference voltage, to output a first error signal when a value of the first code fails within the previously stored first code range.

11. The SoC of claim 10, wherein:
the third test circuit comprises:
a second counter circuit configured to sequentially output second input codes decreasing by a unit code at the specified period;
a second converter circuit configured to decrease a magnitude of a second test voltage by the unit voltage at the specified period and then output the decreased magnitude of the second test voltage, in response to the second input codes; and
a second code comparator configured to determine whether a value of a second code, output to generate a second test voltage determined to have a same voltage as the second reference voltage by the second comparator, falls within a previously stored second code range, and
the third test circuit determines that the second comparator compares the monitoring voltage with a second determination voltage, having a value within a predetermined second comparison range from the second reference voltage, to output a second error signal when the value of the second code falls within the previously stored second code range.

12. A system-on-chip (SoC) comprising:
a monitoring circuit configured to determine whether a monitoring voltage has a value between a first reference voltage and second reference voltage, based on a first supply voltage and a second supply voltage,
the monitoring circuit comprising:
a reference voltage generation circuit configured to generate the first reference voltage and the second reference voltage;
a first comparator configured to compare magnitudes of the monitoring voltage and the first reference voltage; and
a second comparator configured to compare magnitudes of the monitoring voltage and the second reference voltage,
a first test circuit configured to determine whether the first supply voltage has a value within a predetermined first supply range, using the second supply voltage;
a second test circuit configured to determine whether the first reference voltage has a value within a predetermined first reference range; and
a third test circuit configured to determine whether the first comparator compares the magnitude of the monitoring voltage with a magnitude of a first determination voltage having a value within a predetermined first comparison range from the first reference voltage.

13. The SoC of claim 12, wherein:
the reference voltage generation circuit is configured to output a first upper reference voltage and a first lower reference voltage, each having a value within a predetermined range from a previously stored target value of the first supply voltage,
the first test circuit comprises:
a first supply comparator configured to compare the first supply voltage and the first upper reference voltage; and
a second supply comparator configured to compare the first supply voltage and the first lower reference voltage, and
the first supply comparator and the second supply comparator are configured to operate using the second supply voltage.

14. The SoC of claim 12, wherein:
the reference voltage generation circuit comprises:
a basic voltage generation circuit configured to generate a basic voltage;
a first buffer configured to generate the first reference voltage based on the basic voltage; and
a second buffer configured to generate the second reference voltage, lower than the first reference voltage, based on the basic voltage, and
the second test circuit is configured to determine whether the first reference voltage has a value between a first upper voltage and a first lower voltage output from the second buffer.

15. The SoC of claim 12, wherein:
the third test circuit comprises:
a first counter circuit configured to sequentially output first input codes increasing by a unit code at a specified period;
a first converter circuit configured to increase a magnitude of a first test circuit by a unit voltage at the specified period and then output the increased magnitude of the first test circuit, in response to the first input codes; and
a first code comparator configured to determine whether a value of a first code, output to generate the first test voltage determined to have a same value as the first reference voltage by the first comparator, falls within a previously stored first code range, and
the third test circuit is configured to determine that the first comparator compares the monitoring voltage with the first determination voltage, having a value within the first comparison range from the first reference voltage, to output a first error signal when the value of the first code falls within the previously stored first code range.

16. A built-in self-test (BIST) circuit for determining whether a monitoring circuit is operating normally by determining whether a monitoring voltage has a value between a first reference voltage and a second reference voltage, the BIST circuit comprising:
a first test circuit configured to determine whether a first supply voltage has a value within a predetermined first supply range, using a second supply voltage among a first supply voltage and the second supply voltage provided to the monitoring circuit;
a second test circuit configured to determine whether the first reference voltage has a value within a predetermined first reference range; and
a third test circuit configured to determine whether a first comparator compares a magnitude of the monitoring voltage with a magnitude of a first determination voltage having a value within a predetermined first comparison range from the first reference voltage.

17. The BIST circuit of claim 16, wherein:
the first test circuit comprises:
a first supply comparator configured to determine whether the first supply voltage is greater than or equal to a first upper reference voltage; and
a second supply comparator configured to determine whether the first supply voltage is less than or equal to a first lower reference voltage, and
the first supply comparator and the second supply comparator are configured to operate using the second supply voltage.

18. The BIST circuit of claim 17, wherein:
the first test circuit comprises a first supply multiplexer configured to selectively output either one of the first upper reference voltage and the first lower reference voltage, based on an enable signal,
the first supply comparator is configured to compare magnitudes of a voltage, output from the first supply multiplexer, and the first supply voltage, and
the first test circuit is configured to determine that the first supply voltage has a value between the first upper reference voltage and the first lower reference voltage when a level of a signal output from the first supply comparator transitions, in response to the enable signal.

19. The BIST circuit of claim 16, wherein:
the second test circuit is configured to determine whether a first reference voltage, output from a first buffer, has a value between a first upper voltage and a first lower voltage output from a second buffer in which the second reference voltage is generated.

20. The BIST circuit of claim 16, wherein:
the third test circuit comprises:
a first counter circuit configured to sequentially output first input codes increasing by a unit code at a specified period;
a first converter circuit configured to increase a magnitude of a first test voltage by a unit voltage at the specified period and then output the increased magnitude of the first test voltage, in response to the first input codes; and
a first code comparator configured to determine whether a value of a first code corresponding to the first test voltage falls within a previously stored first code range at a time point at which the monitoring circuit determines that the first test voltage is greater than or equal to the first reference voltage, and
the third test circuit is configured to determine that the monitoring circuit compares the monitoring voltage with the first determination voltage, having a value within the first comparison range from the first reference voltage, to output a first error signal.
